(19) United States
(12) Patent Application Publication
(10) Pub. No.: US 2026/0212819 A1
(43) Pub. Date: Jul. 23, 2026

(54) FREQUENCY VARIABLE DISPLAY APPARATUS AND DRIVING METHOD THEREOF

(71) Applicant: LG Display Co., Ltd., Seoul (KR)

(72) Inventors: Soek Min CHOI, Paju-si (KR); Tae Woo KIM, Paju-si (KR); Moo Kyoung HONG, Paju-si (KR)

(73) Assignee: LG Display Co., Ltd., Seoul (KR)

(21) Appl. No.: 19/439,741

(22) Filed: Jan. 5, 2026

(30) Foreign Application Priority Data
Jan. 21, 2025 (KR) 10-2025-0008905

(51) Int. Cl. G09G 3/3233; G09G 3/00

(52) U.S. Cl. CPC G09G 3/3233; G09G 3/006; G09G 2310/0245; G09G 2310/08; G09G 2320/0247; G09G 2330/023; G09G 2330/12

(57) ABSTRACT

A display apparatus includes a display panel including a plurality of subpixels disposed therein, each of the plurality of subpixels including a driving element and a light emitting element connected between a high-level source voltage and a low-level source voltage, a sensing circuit configured to, during an n^{th} (where n is a natural number) frame, sense a driving current of an (n-1)^{th} frame flowing through the driving element to output a sensing value, before a gate-source voltage of the n^{th} frame on the driving element is programmed, a timing controller configured to output a power control signal, based on the sensing value, and a power circuit configured to adjust a voltage level of the low-level source voltage, based on the power control signal.

### CROSS-REFERENCE TO RELATED APPLICATIONS

This application claims the benefit of and priority to Korean Patent Application No. 10-2025-0008905 filed on January 21, 2025, the entire contents of which are incorporated herein by reference for all purposes.

### BACKGROUND

### Technical Field

The present disclosure relates to a frequency variable display apparatus.

### Description of Related Art

Frequency variable display apparatuses vary a frame frequency of an image displayed on a screen, based on an attribute of video data received from an external video source. Frequency variable display apparatuses support a variable refresh rate (VRR) function which varies a frame frequency within a predetermined frequency range.

When a frame frequency is rapidly changed from a low-speed frame to a high-speed frame or to be opposite thereto by a VRR operation, a flicker phenomenon caused by a recognition luminance deviation may be recognized by a user. To decrease the recognition luminance deviation, luminance algorithm technology which adjusts a data gain according to a frame frequency has been known. However, in such technology, because a data gain of a current frame is determined based on frequency information about a previous frame, there is a limitation in decreasing a recognition luminance deviation (i.e., VRR flicker) between a first frame immediately after a frame frequency is rapidly changed and a frame immediately before the first frame.

The description of related art should not be considered prior art merely because it is mentioned in or associated with this section. The description of related art includes information that describes one or more aspects of the subject technology, and the description in this section does not limit the scope of the present disclosure.

### SUMMARY

To overcome the aforementioned problem of the related art, one or more aspects of the present disclosure may provide a frequency variable display apparatus and a driving method thereof, which may decrease VRR flicker occurring in a rapid change condition of a frame frequency.

To achieve these aspects and other advantages and in accordance with the purpose of the disclosure, as embodied and broadly described herein, a display apparatus includes: a display panel including a plurality of subpixels disposed therein, each of the plurality of subpixels including a driving element and a light emitting element connected between a high-level source voltage and a low-level source voltage; a sensing circuit configured to, during an n^{th} (where n is a natural number) frame, sense a driving current of an (n-1)^{th} frame flowing through the driving element to output a sensing value, before a gate-source voltage of the n^{th} frame on the driving element is programmed; a timing controller configured to output a power control signal, based on the sensing value; and a power circuit configured to adjust a voltage level of the low-level source voltage, based on the power control signal.

In another aspect of the present disclosure, a display apparatus includes: a display panel including a plurality of subpixels disposed therein, each of the plurality of subpixels including a driving element and a light emitting element connected between a high-level source voltage and a low-level source voltage; a sensing circuit configured to, during an n^{th} (where n is a natural number) frame, sense a driving current of an (n-1)^{th} frame flowing through the driving element before a gate-source voltage of the n^{th} frame on the driving element is programmed; and a power circuit configured to adjust a voltage level of the low-level source voltage, based on a driving current sensing value of the (n-1)^{th} frame, wherein, when the number of black subpixels of an (n-1)^{th} frame image corresponding to the driving current of the (n-1)^{th} frame is a first value within a predetermined range, the power circuit outputs the low-level source voltage at a default voltage level in the n^{th} frame, and when the number of black subpixels of the (n-1)^{th} frame image corresponding to the driving current of the (n-1)^{th} frame is a second value outside the predetermined range, the power circuit outputs the low-level source voltage at an adjustment voltage level which is lower than the default voltage level, in the n^{th} frame.

In another aspect of the present disclosure, a driving method of a display apparatus including a display panel including a plurality of subpixels disposed therein, each of the plurality of subpixels including a driving element and a light emitting element connected between a high-level source voltage and a low-level source voltage, includes: during an n^{th} (where n is a natural number) frame, sensing a driving current of an (n-1)^{th} frame flowing through the driving element to output a sensing value, before a gate-source voltage of the n^{th} frame on the driving element is programmed; outputting a power control signal, based on the sensing value; and adjusting a voltage level of the low-level source voltage, based on the power control signal.

In another aspect of the present disclosure, a driving method of a display apparatus including a display panel including a plurality of subpixels disposed therein, each of the plurality of subpixels including a driving element and a light emitting element connected between a high-level source voltage and a low-level source voltage, includes: during an n^{th} (where n is a natural number) frame, sensing a driving current of an (n-1)^{th} frame flowing through the driving element before a gate-source voltage of the n^{th} frame on the driving element is programmed; and adjusting a voltage level of the low-level source voltage, based on a driving current sensing value of the (n-1)^{th} frame, wherein the adjusting of the voltage level of the low-level source voltage includes: when the number of black subpixels of an (n-1)^{th} frame image corresponding to the driving current of the (n-1)^{th} frame is a first value within a predetermined range, outputting the low-level source voltage at a default voltage level in the n^{th} frame; and when the number of black subpixels of the (n-1)^{th} frame image corresponding to the driving current of the (n-1)^{th} frame is a second value outside the predetermined range, outputting the low-level source voltage at an adjustment voltage level which is lower than the default voltage level, in the n^{th} frame.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further features, advantages, and aspects are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a block diagram illustrating a frequency variable display apparatus according to an embodiment of the present disclosure;

FIG. 2 is a diagram illustrating a connection configuration of a pixel according to an embodiment of the present disclosure;

FIG. 3 is a diagram illustrating an arrangement configuration of an organic light emitting diode (OLED) multi-stack and a color filter of a pixel according to an embodiment of the present disclosure;

FIG. 4 is a diagram illustrating an example of an OLED multi-stack according to an embodiment of the present disclosure;

FIG. 5 is a diagram illustrating a vertical active period and a vertical blank period configuring one frame time;

FIG. 6 is a diagram illustrating an example where a length of a vertical front porch included in a vertical blank period varies based on a level of a frame frequency;

FIG. 7 is a diagram illustrating an example where recognition luminance is changed based on a level of a frame frequency;

FIG. 8 is a diagram illustrating VRR flicker occurring in a rapid change condition of a frame frequency;

FIGS. 9 and 10 are diagrams illustrating an example where the visibility of VRR flicker is higher in a low gray level than a high gray level;

FIG. 11 is a diagram illustrating a driving method for reducing VRR flicker;

FIG. 12 is a diagram illustrating a concept which senses a driving current of an (n-1)^{th} frame before a driving current programming operation of an n^{th} frame;

FIG. 13 is a diagram illustrating in detail a driving waveform of a subpixel of an n^{th} frame;

FIG. 14A is a diagram illustrating an operation of a subpixel in an XX period of FIG. 13;

FIG. 14B is a diagram illustrating an operation of a subpixel in an XY period of FIG. 13;

FIG. 14C is a diagram illustrating an operation of a subpixel in an XZ period of FIG. 13;

FIG. 15 is a diagram illustrating a connection configuration between a timing controller, a power circuit, and a sensing circuit for adjusting a voltage level of a low-level source voltage according to an embodiment of the present disclosure;

FIG. 16 is a diagram illustrating a configuration example of a power circuit adjusting a voltage level of a low-level source voltage, based on the number of black subpixels;

FIG. 17 is a diagram illustrating an example where a low-level source voltage is adjusted to be lower in a low grayscale image frame than a high grayscale image frame;

FIGS. 18A and 18B are diagrams illustrating an example where a voltage level of a low-level source voltage is differently adjusted in a first display area and a second display area of a display panel;

FIG. 19 is a diagram illustrating an example where a Coled charge time is reduced by the down adjustment of a low-level source voltage;

FIG. 20 is a diagram illustrating a Vgs variation of when a low-level source voltage is applied at a default level;

FIG. 21 is a diagram illustrating a Vgs variation of when a low-level source voltage is applied at a voltage level which is lower than the default level;

FIG. 22 is a diagram illustrating an example where VRR flicker is reduced when a low-level source voltage is down-adjusted;

FIGS. 23 and 24 are diagrams illustrating an example where an abnormal flashing phenomenon occurs due to a capacitance deviation of capacitors configuring an OLED multi-stack; and

FIG. 25 is a diagram illustrating an example where △Vgs is reduced when a low-level source voltage decreases, and thus, an over-emission current level is lowered, and flashing is prevented.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Hereinafter, the present disclosure will be described more fully with reference to the accompanying drawings, in which example embodiments of the disclosure are shown. The disclosure may, however, be embodied in many different forms and should not be construed as being limited to the embodiments set forth herein; rather, these embodiments are provided so that this disclosure will be thorough and complete, and will fully convey the concept of the disclosure to those skilled in the art.

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Furthermore, the present disclosure is only defined by scopes of claims.

The shapes, sizes, ratios, angles, numbers and the like disclosed in the drawings for description of various embodiments of the present disclosure to describe embodiments of the present disclosure are merely example and the present disclosure is not limited thereto. Like reference numerals refer to like elements throughout. Throughout this specification, the same elements are denoted by the same reference numerals. As used herein, the terms “comprise”, “having”, “including” and the like suggest that other parts can be added unless the term “only” is used. As used herein, the singular forms “a”, “an”, and “the” are intended to include the plural forms as well, unless context clearly indicates otherwise. In one or more examples, unless expressly stated otherwise, an element may be one or more elements; and an element may include a plurality of elements.

Elements in various embodiments of the present disclosure are to be interpreted as including margins of error even without explicit statements.

In describing a position relationship, for example, when a position relation between two parts is described as “on~”, “over~”, “under~”, and “next~”, one or more other parts may be disposed between the two parts unless “just” or “direct” is used.

It will be understood that, although the terms “first”, “second”, etc. may be used herein to describe various elements, these elements should not be limited by these terms. These terms are merely used to refer to one element separately from another. For example, a first element could be termed a second element, and, similarly, a second element could be termed a first element, without departing from the scope of the present disclosure. In one or more aspects, unless stated otherwise, the term “nth” may refer to “nnd” (e.g., 2nd where n is 2), or “nrd” (e.g., 3rd where n is 3), and n may be a natural number.

In the following description, when the detailed description of the relevant known function or configuration is determined to unnecessarily obscure the important point of the present disclosure, the detailed description will be omitted. Hereinafter, embodiments of the present disclosure will be described in detail with reference to the accompanying drawings.

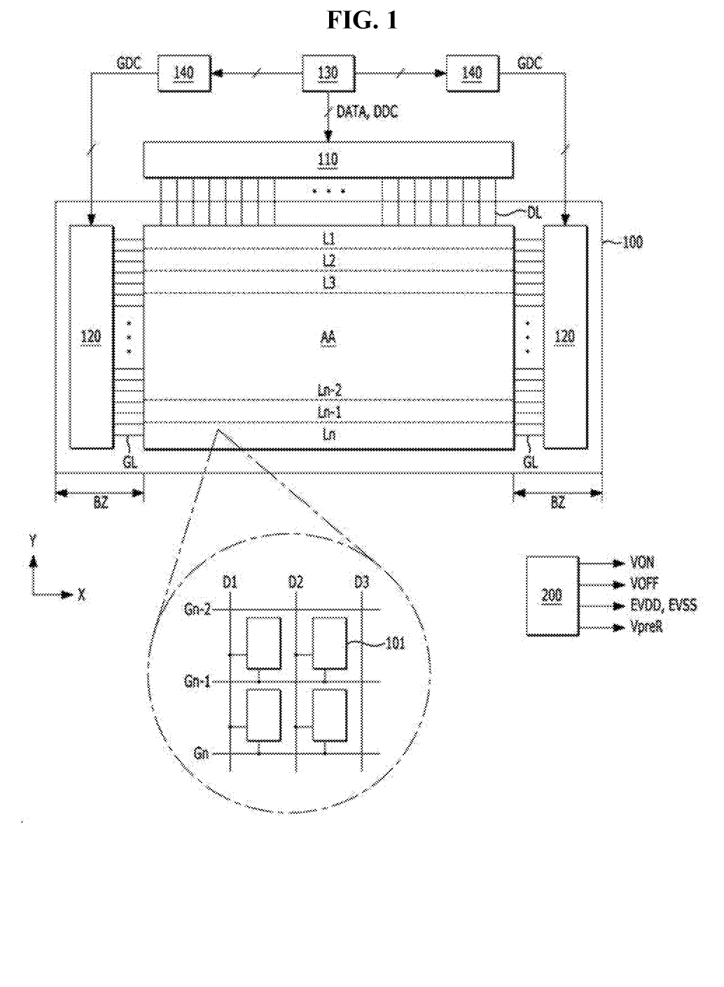

FIG. 1 is a block diagram illustrating a frequency variable display apparatus according to an embodiment of the present disclosure.

Referring to FIG. 1, a display panel 100 may include a screen AA which displays an input image. The screen AA may include a pixel array which displays pixel data (hereinafter referred to as “image data”) DATA of an input image. The pixel array may include a plurality of data lines DL, a plurality of gate lines GL intersecting with the data lines DL, a plurality of reference voltage lines, and a plurality of pixels.

The pixels may be arranged on the screen AA in a matrix type defined by the data lines DL, the gate lines GL, and the reference voltage lines. The pixels may be arranged as various types, such as a stripe type and a diamond type as well as a matrix type, on the screen AA.

The pixel array may include a plurality of pixel columns and a plurality of pixel rows L1 to Ln intersecting with the pixel columns. Each of the pixel columns may include pixels which are arranged in a Y-axis direction. A pixel line may include pixels which are arranged in an X-axis direction. One vertical period may be one frame period needed for writing image data DATA of one frame in all pixels of the screen. One horizontal period may be a time obtained by dividing one frame period by the number of pixel rows L1 to Ln. One horizontal period may be a time needed for writing the image data DATA of one pixel row, sharing a gate line GL, in pixels of one pixel row.

Each of the pixels may include a red (R) subpixel 101, a green (G) subpixel 101, a blue (B) subpixel 101, and a white (W) subpixel 101 for implementing colors.

The frequency variable display apparatus according to the present embodiment may be implemented as an electroluminescent display apparatus. In this case, a pixel circuit of the frequency variable display apparatus may include a light emitting element, a driving element, one or more switch elements, and a capacitor. The light emitting element may be implemented as an organic light emitting diode (OLED). A driving current which allows the light emitting element to emit light may be adjusted based on a gate-source voltage of the driving element. Each of the driving element and the switch element may be implemented as a transistor. A semiconductor layer of the transistor may include amorphous silicon or polysilicon. Semiconductor layers of at least some of transistors may include oxide. The pixel circuit may be connected to a data line DL and a gate line GL. In FIG. 1, “D1 to D3” illustrated in a circle may be data lines, and “Gn-2 to Gn” may be gate lines. Each of the subpixels 101 of FIG. 1 may include the same pixel circuit.

Touch sensors may be disposed on the display panel 100. The touch sensors may be arranged as an on-cell or add-on type on the screen AA of the display panel 100, or may be implemented as in-cell type touch sensors embedded in the pixel array. A touch input may be sensed through the touch sensors, or may be sensed through only pixels even without touch sensors.

A source driver 110 may convert the image data DATA, received from a timing controller 130, into gamma compensation voltages by using a digital-to-analog converter (DAC) to generate data voltages. The source driver 110 may supply the data voltages to the data lines DL. The data voltages may be supplied to the data lines DL and may be applied to gate electrodes of the driving elements through the switch elements of the subpixels 101. The source driver 110 may supply an initialization voltage VpreR, received from a power circuit 200, to reference voltage lines connected to the subpixels. The initialization voltage VpreR may be supplied to the reference voltage lines and may be applied to a source electrode of the driving element through a switch element of each subpixel 101.

The source driver 110 may be implemented with one or more source drive integrated circuits (ICs). The source drive IC may be connected to the timing controller 130 through an internal interface circuit. The internal interface circuit may be implemented as an embedded clock point to point interface (EPI). The source drive IC may further include a touch driver. The touch driver may generate a touch sensor driving signal and may convert an electric charge variation of a touch sensor into touch raw data. The touch driver may transfer the touch raw data to a host system (not shown) through a separate interface circuit. The separate interface circuit may be implemented as a serial peripheral interface (SPI).

A gate driver 120 may be provided in a bezel area BZ disposed outside the screen AA in the display panel 100. The bezel area BZ may not display an image. The gate driver 120 may sequentially supply a gate signal, synchronized with data voltages, to the gate lines GL according to control by the timing controller 130. The gate signal may simultaneously activate pixels of the same pixel row into which a data voltage is charged. The gate driver 120 may output the gate signal by using one or more shift registers and may shift the gate signal. The gate signal may be referred to as a scan signal. The scan signal may include a gate on voltage VON and a gate off voltage VOFF, which are received from the power circuit 200.

The timing controller 130 may receive video data DATA and a timing signal, synchronized with the video data DATA, from the host system (not shown). The timing signal may include a vertical synchronization signal Vsync, a horizontal synchronization signal Hsync, a clock signal DCLK, and a data enable signal DE. The vertical synchronization signal Vsync may define a vertical period (i.e., one frame). The horizontal synchronization signal Hsync may define a horizontal period. The data enable signal DE may define a time (i.e., a vertical active period) where data voltages are input to subpixels in a vertical period. The other time, except the vertical active period, of the vertical period may be a vertical blank period. The data enable signal DE may swing in the vertical active period and may not swing in the vertical blank period.

The timing controller 130 may generate a source timing control signal DDC for controlling an operation timing of the source driver 110 and a gate timing control signal GDC for controlling an operation timing of the gate driver 120, based on the timing signal Vsync, Hsync, and DE received from the host system.

The host system may be one of a television (TV), a set-top box, a navigation system, a personal computer (PC), a home theater, an automotive display system, a mobile device, and a wearable device. In the mobile device and the wearable device, the source driver 110, the timing controller 130, and a level shifter 140 may be integrated into one drive IC.

The level shifter 140 may shift a logic voltage level of the gate timing control signal GDC, output from the timing controller 130, to the gate on voltage VON or the gate off voltage VOFF to supply to the gate driver 120. A low logic voltage of the gate timing control signal GDC may be down-shifted to the gate off voltage VOFF, and a high logic voltage of the gate timing control signal GDC may be up-shifted to the gate on voltage VON.

The power circuit 200 may generate various source voltages needed for panel driving. The power circuit 200 may generate the gate on voltage VON and the gate off voltage VOFF needed for generating of the scan signal, generate a high level source voltage EVDD and a low level source voltage EVSS which are to be supplied to each subpixel 101, and generate the initialization voltage VpreR which is to be supplied to a reference voltage line.

The timing controller 130, the source driver 110, the gate driver 120, and the power circuit 200 may be elements configuring a flicker compensation circuit according to an embodiment of the present disclosure. The flicker compensation circuit may decrease a voltage level of the low-level source voltage EVSS, based on the number of black subpixels included in a previous frame image, and thus, may reduce a recognition luminance deviation between frames occurring in a rapid change condition of a frame frequency. Particularly, when a data voltage is low based on a low gray level, charge time of an internal capacitor (hereinafter referred to as Coled) of a light emitting element OLED may increase, and due to this, VRR flicker may occur. On the other hand, the flicker compensation circuit according to an embodiment of the present disclosure may decrease a voltage level of the low-level source voltage EVSS, and thus, may shorten the charge time of Coled and may reduce VRR flicker.

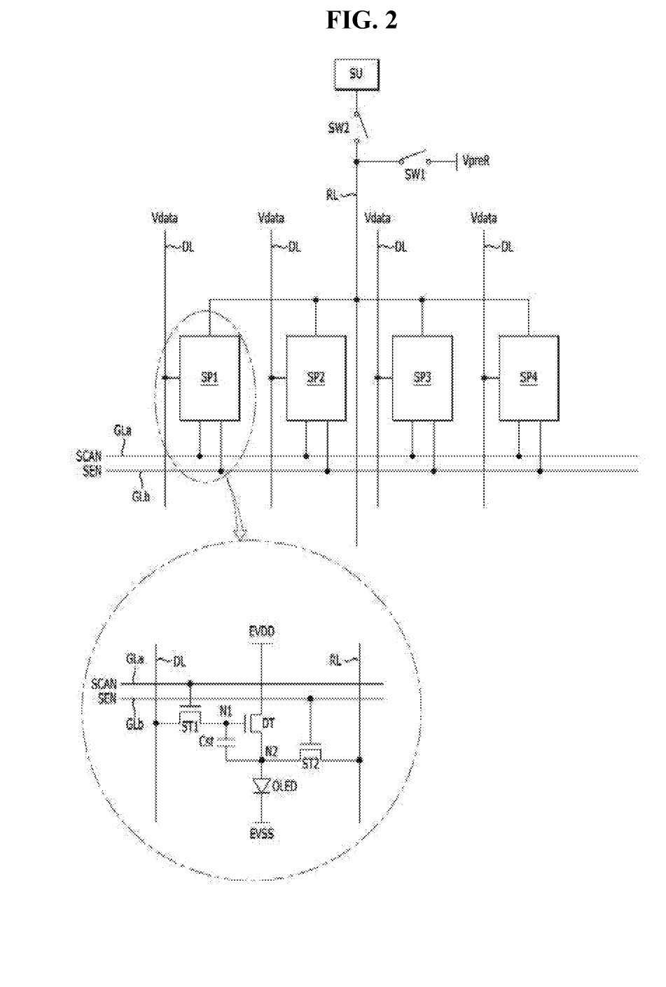

FIG. 2 is a diagram illustrating a connection configuration of a pixel PXL according to an embodiment of the present disclosure.

Referring to FIG. 2, the pixel PXL may include four subpixels SP1 to SP4 which share a reference voltage line RL. The four subpixels SP1 to SP4 may be R, G, B, and W subpixels for configuring the same pixel. Each of the subpixels SP1 to SP4 may include, for example, a light emitting element OLED, a driving transistor DT, first and second switch transistors ST1 and ST2, and a storage capacitor Cst.

The light emitting element OLED may emit light with a driving current supplied from the driving transistor DT to implement luminance. An anode electrode of the light emitting element OLED may be connected to a second node N2, and a cathode electrode thereof may be connected to an input terminal of a low-level source voltage EVSS.

The driving transistor DT may be a driving element which generates the driving current based on a gate-source voltage thereof to supply the driving current to the light emitting element OLED. A gate electrode of the driving transistor DT may be connected to a first node N1, a drain electrode thereof may be connected to an input terminal of a high-level source voltage EVDD, and a source electrode thereof may be connected to the second node N2.

A gate electrode of the first switch transistor ST1 may be connected to a scan gate line GLa, a first electrode thereof may be connected to a data line DL, and a second electrode thereof may be connected to the first node N1.

A gate electrode of the second switch transistor ST2 may be connected to a sense gate line GLb. A first electrode of the second switch transistor ST2 may be connected to the reference voltage line RL, and a second electrode thereof may be connected to the second node N2.

One electrode of the storage capacitor Cst may be connected to the first node N1, and the other electrode thereof may be connected to the second node N2.

A first switch SW1 and a second switch SW2 may be further connected to the reference voltage line RL. The first switch SW1 may connect an input terminal of the initialization voltage VpreR to the reference voltage line RL. The second switch SW2 may connect the reference voltage line RL to a sensing circuit SU for sensing the driving current flowing through the driving transistor DT.

In an n^{th} (where n may be a natural number) frame, the first switch SW1 may be turned on so that a gate-source voltage of the driving transistor DT is programmed. In the n^{th} frame, before the gate-source voltage of the driving transistor DT is programmed, the second switch SW2 may be turned on so that a driving current of an (n-1)^{th} frame flowing through the driving transistor DT is sensed.

While the second switch SW2 is being connected to the reference voltage line RL, an electrical connection between the first switch SW1 and the reference voltage line RL may be disconnected. While the second switch SW2 is being connected to the reference voltage line RL, a driving current sensing operation may be performed by the sensing circuit SU.

The first switch SW1, the second switch SW2, and the sensing circuit SU may be included in the source driver 110.

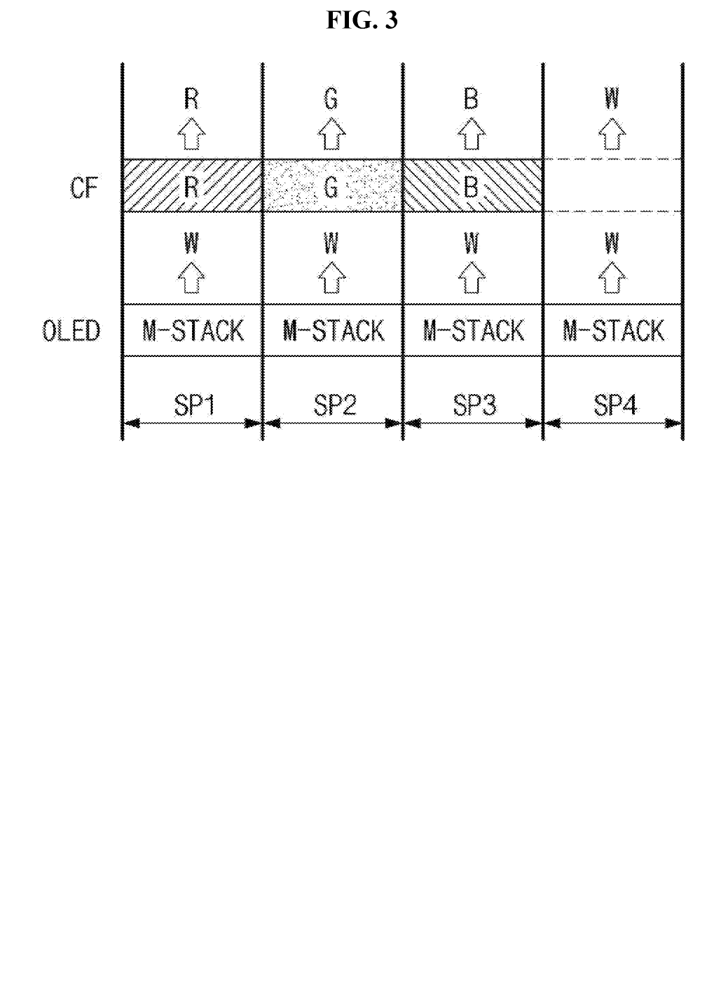

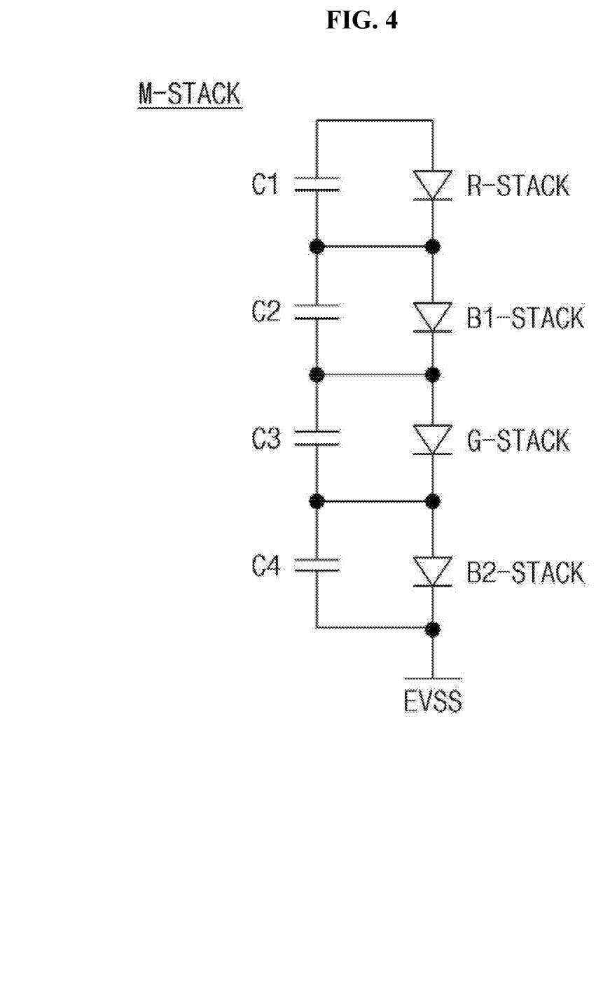

FIG. 3 is a diagram illustrating an arrangement configuration of an OLED multi-stack and a color filter of a pixel according to an embodiment of the present disclosure. FIG. 4 is a diagram illustrating an example of an OLED multi-stack according to an embodiment of the present disclosure.

Referring to FIGS. 3 and 4, a light emitting element OLED of each of R, G, B, and W subpixels SP1 to SP4 may be implemented in a multi-stack structure M-STACK. As an example of the multi-stack structure M-STACK, there may be a 4-stack structure. The 4-stack structure may be configured with an R stack, a B1 stack, a G stack, and a B2 stack, which are sequentially and serially connected to one another. An internal capacitor C1 may be formed at both anode-cathode ends of the R stack, an internal capacitor C2 may be formed at both anode-cathode ends of the B1 stack, an internal capacitor C3 may be formed at both anode-cathode ends of the G stack, and an internal capacitor C4 may be formed at both anode-cathode ends of the B2 stack.

The light emitting element OLED of each of the R, G, B, and W subpixels SP1 to SP4 may include the 4-stack structure to generate white (W) light. The white (W) light may be converted into red (R) light, green (G) light, or blue (B) light in a color filter array disposed on a multi-stack array.

In the R subpixel SP1, the white (W) light generated by the light emitting element OLED may pass through an R color filter CF-R and may thus be converted into red (R) light, and then, may be output to the outside. In the G subpixel SP2, the white (W) light generated by the light emitting element OLED may pass through a G color filter CF-G and may thus be converted into green (G) light, and then, may be output to the outside. In the B subpixel SP3, the white (W) light generated by the light emitting element OLED may pass through a B color filter CF-B and may thus be converted into blue (B) light, and then, may be output to the outside. Furthermore, in the W subpixel SP4, the white (W) light generated by the light emitting element OLED may bypass a color filter CF and may be output to the outside.

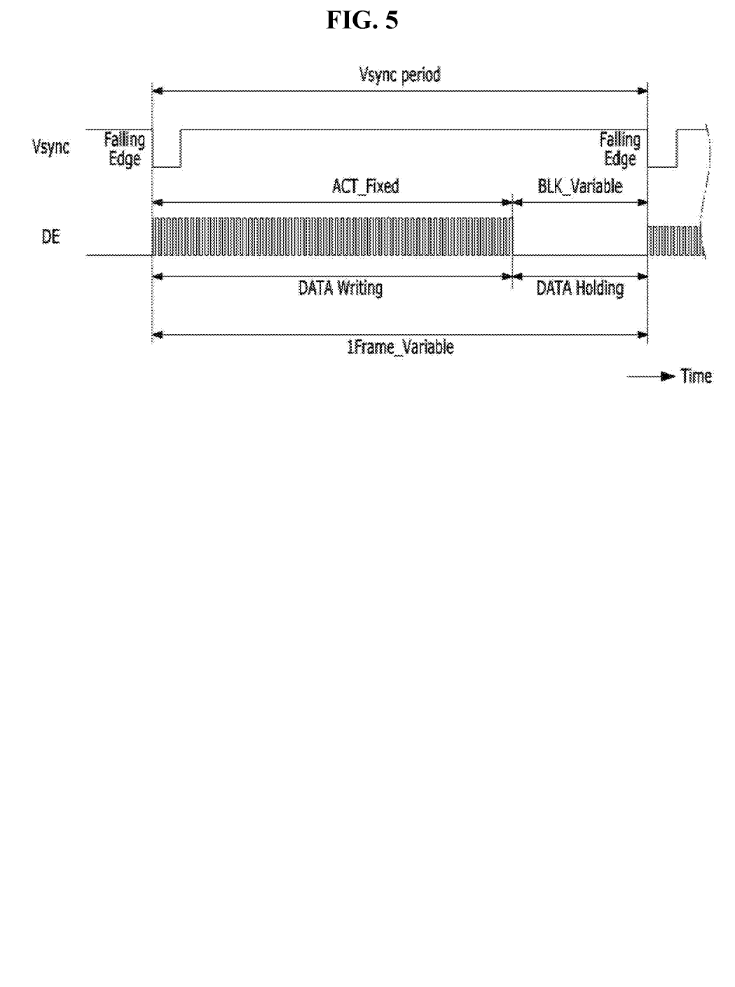

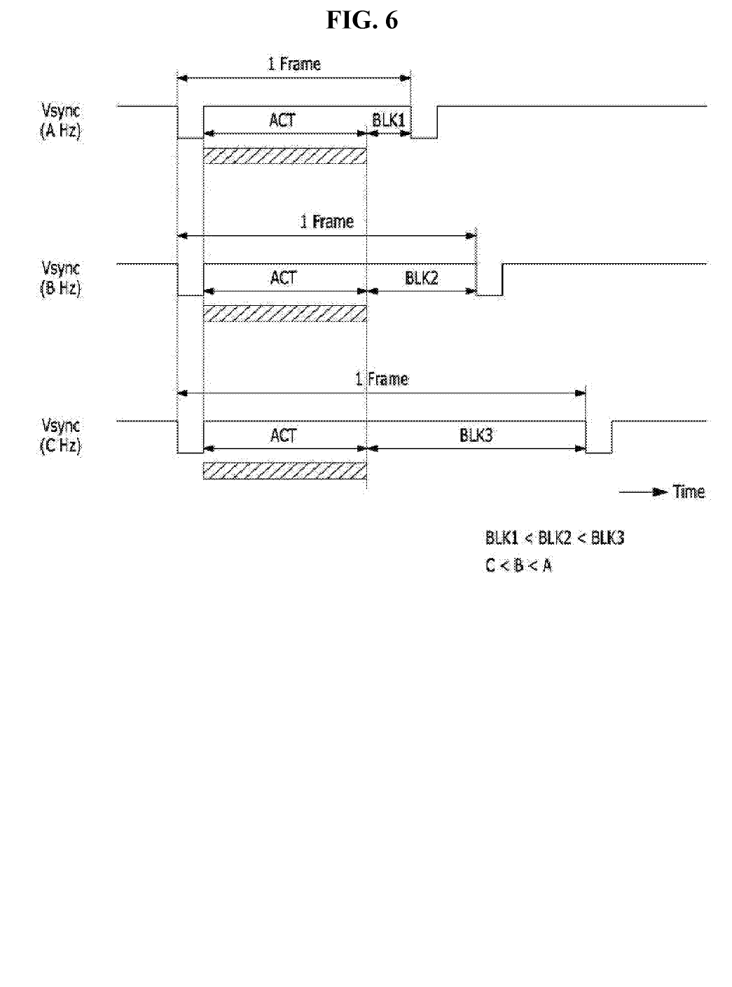

FIG. 5 is a diagram illustrating a vertical active period and a vertical blank period configuring one frame time. FIG. 6 is a diagram illustrating an example where a length of a vertical front porch included in a vertical blank period varies based on a level of a frame frequency.

Referring to FIG. 5, one frame time (vertical period) may be defined by a vertical synchronization signal Vsync. The one frame time (vertical period) may be defined as a time interval between adjacent falling edges (or rising edges) of the vertical synchronization signal Vsync.

A vertical active period ACT and a vertical blank period BLK in the one frame time (vertical period) may be defined by a data enable signal DE. The vertical active period ACT may be a period during which the data enable signal DE swings, and the vertical blank period BLK may be a period during which the data enable signal DE does not swing.

The frequency variable display apparatus according to the present embodiment may operate in a VRR mode where a length of one frame varies. In the VRR mode, as in FIG. 6, a frame frequency may be changed to A, B, and C Hz. When a frame frequency is changed, a length of one frame time may vary based thereon. In the VRR mode, a length of the vertical active period ACT may be fixed to a predetermined certain value, and a length of the vertical blank period BLK may vary based on a frame frequency. A length of the vertical blank period may be BLK1, based on a frame frequency of A Hz, a length of the vertical blank period may be BLK2, based on a frame frequency of B Hz, and a length of the vertical blank period may be BLK3, based on a frame frequency of C Hz. Here, when A>B>C, BLK1<BLK2<BLK3.

During the vertical active period ACT of a fixed length, a gate-source voltage setting (i.e., driving current programming) operation may be performed in subpixels, based on a data voltage corresponding to image data DATA. During the vertical blank period BLK of a variable length, a gate-source voltage set in subpixels may be held.

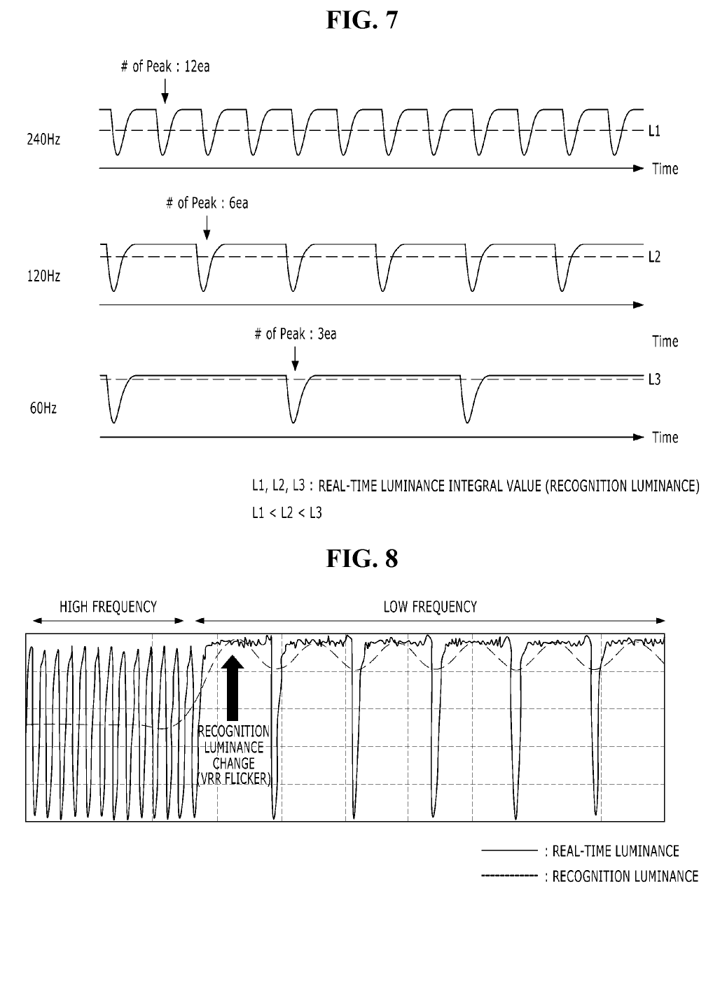

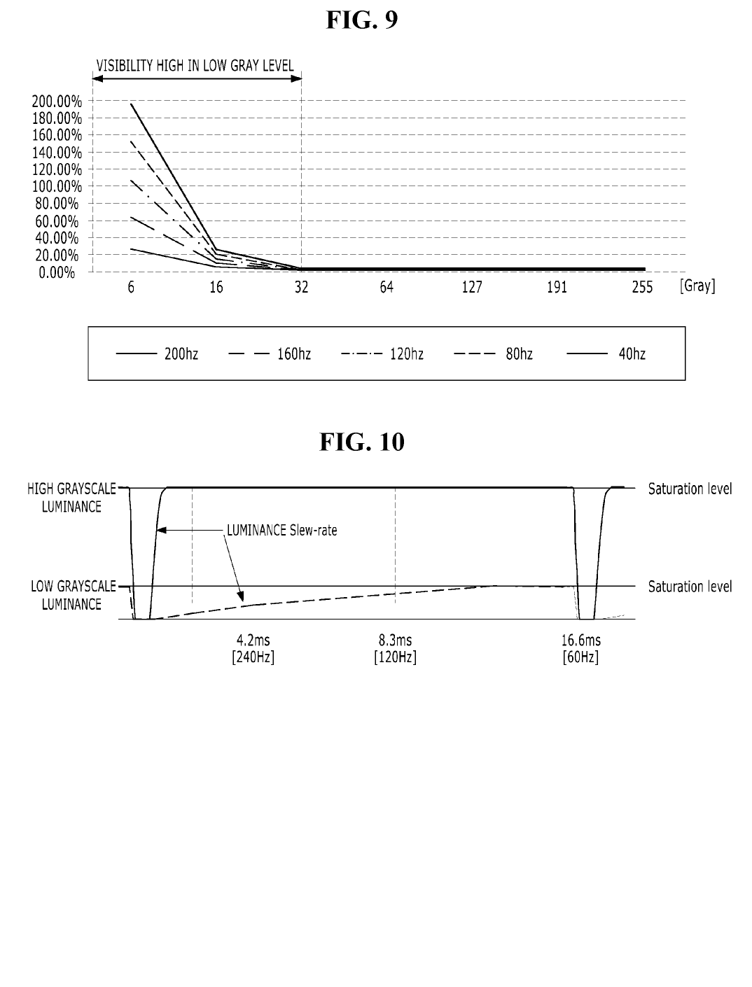

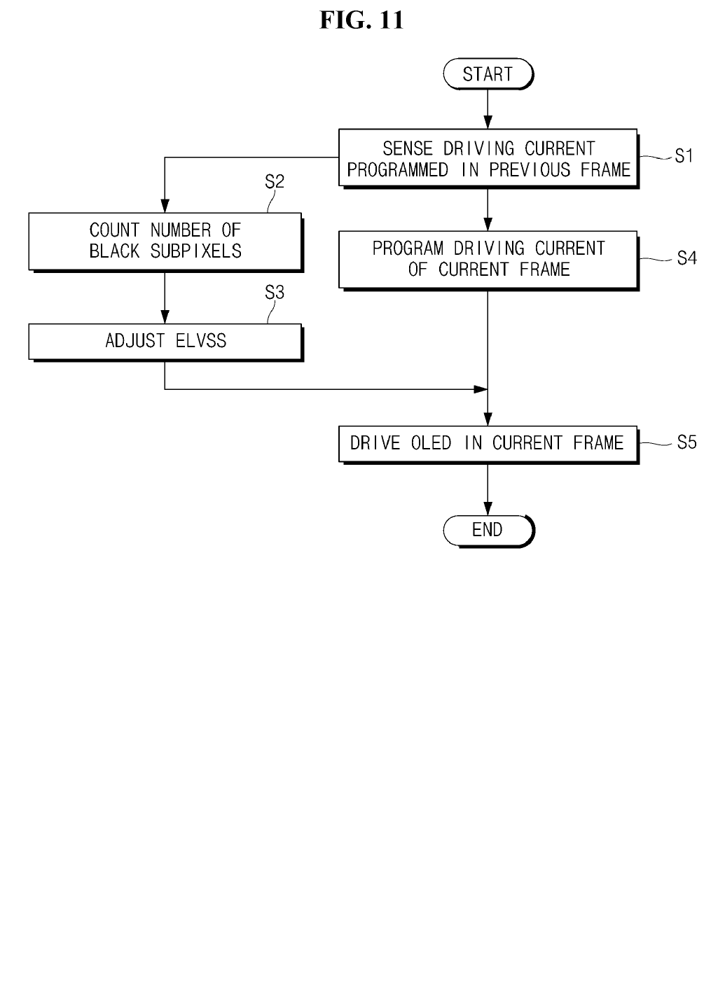

FIG. 7 is a diagram illustrating an example where recognition luminance is changed based on a level of a frame frequency. FIG. 8 is a diagram illustrating VRR flicker occurring in a rapid change condition of a frame frequency. FIGS. 9 and 10 are diagrams illustrating an example where the visibility of VRR flicker is higher in a low gray level than a high gray level.

Peak low luminance points of FIGS. 7 and 8 may be points at which driving current programming operations are performed. An emission operation of a light emitting element OLED may stop while the driving current programming operation is being performed, and the emission operation of the light emitting element OLED may be performed after the driving current programming operation is performed.

The driving current programming operation and the emission operation may be successively performed in one frame. The number of driving current programming operations may increase as the number of frame arrangements in a predetermined time increases, namely, a frame frequency increases, and thus, recognition luminance may be lowered. For example, the number of driving current programming operations in a predetermined time in a frame frequency of 240 Hz may be twelve, the number of driving current programming operations in a predetermined time in a frame frequency of 120 Hz may be six, and the number of driving current programming operations in a predetermined time in a frame frequency of 60 Hz may be three. As a result, a real-time luminance integral value (i.e., recognition luminance) of a frame frequency of 240 Hz may be L1, a real-time luminance integral value (i.e., recognition luminance) of a frame frequency of 120 Hz may be L2 which is higher than L1, and a real-time luminance integral value (i.e., recognition luminance) of a frame frequency of 60 Hz may be L3 which is higher than L2.

As described above, when it is assumed that a gray level of a display image is constant, recognition luminance may be relatively higher in a case, where a frame frequency is a low frequency, than a case where the frame frequency is a high frequency. Accordingly, VRR flicker caused by a change in recognition luminance may occur when the frame frequency is changed from a high frequency to a low frequency.

VRR flicker, as in FIGS. 9 and 10, may be perceived relatively higher in a low grayscale period than a high grayscale period. In a case where a time taken until reaching a target luminance saturation level immediately after driving current programming is defined as a luminance slew rate, a luminance slew rate of a high grayscale image may be relatively greater than a luminance slew rate of a low grayscale image. Accordingly, VRR flicker caused by a change in frequency may not be largely issued in a high grayscale image, but may be clearly recognized when displaying a low grayscale image.

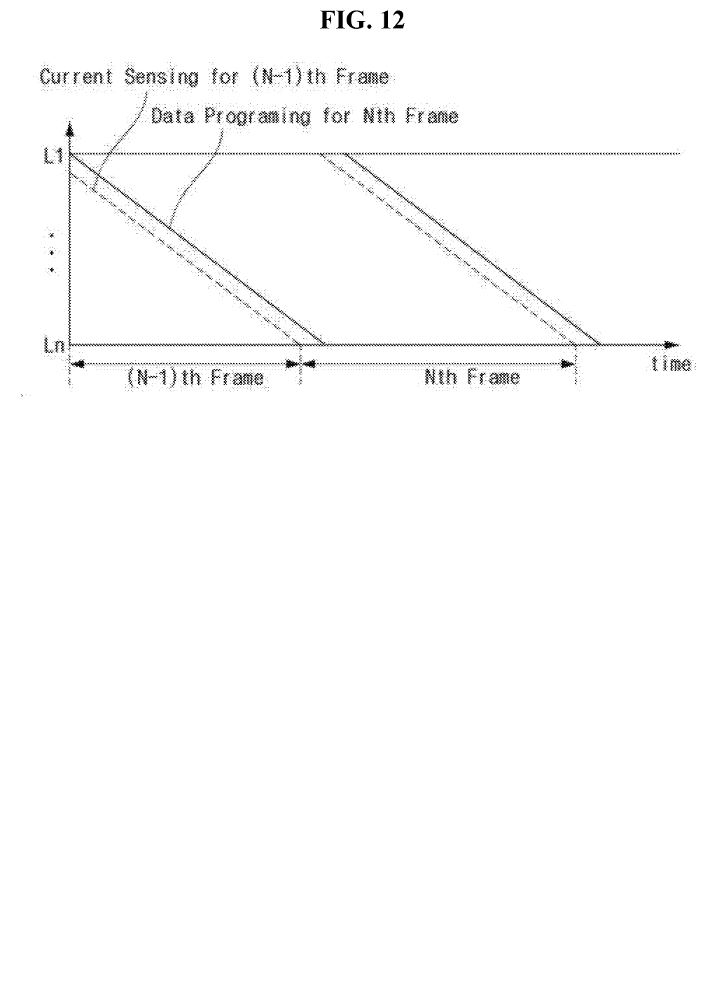

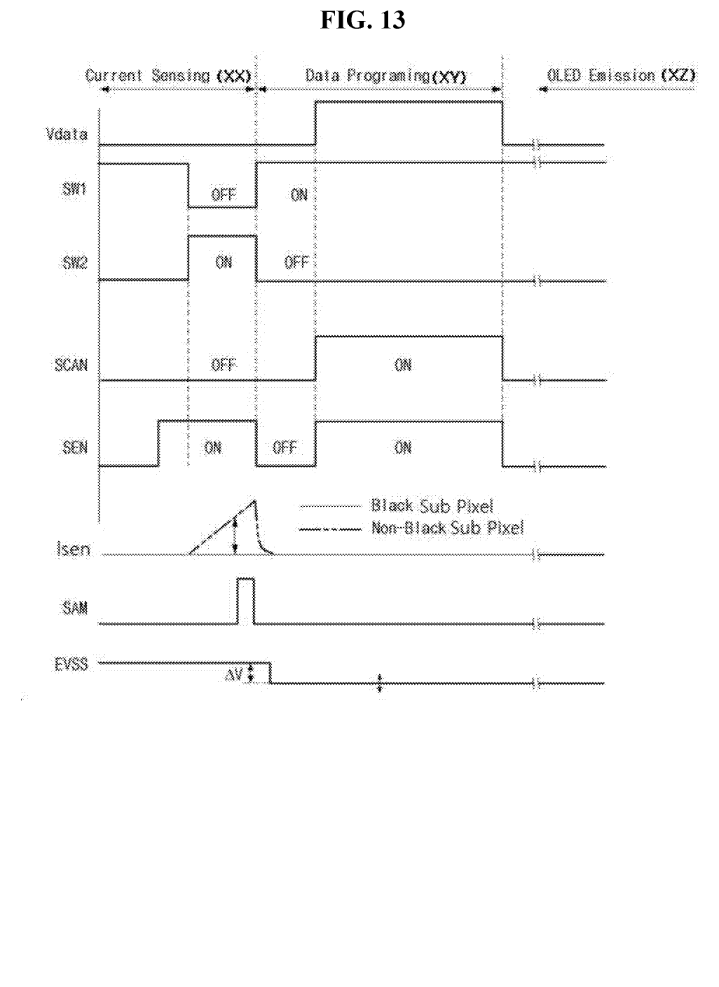

FIG. 11 is a diagram illustrating a driving method for reducing VRR flicker. FIG. 12 is a diagram illustrating a concept which senses a driving current of an (n-1)^{th} frame before a driving current programming operation of an n^{th} frame.

Referring to FIGS. 11 and 12, a flicker compensation circuit according to an embodiment of the present disclosure may sense, by units of subpixel, a driving current programmed in an (n-1)^{th} frame (or a previous frame) in step S1. Such a sensing operation may be performed on all subpixels and may be sequentially performed by units of one pixel row. The flicker compensation circuit may sense the driving current of the (n-1)^{th} frame flowing through a driving transistor to output a sensing value, before a gate-source voltage of an n^{th} frame (or a current frame) is programmed.

The flicker compensation circuit may count the number of black subpixels included in an (n-1)^{th} frame image, based on the sensing value in step S2, and when the number of black subpixels is less than a predetermined register setting value, the flicker compensation circuit may output a low-level source voltage EVSS at a default voltage level, and when the number of black subpixels is greater than or equal to the predetermined register setting value, the flicker compensation circuit may output the low-level source voltage EVSS at an adjustment voltage level which is lower than the default voltage level in step S3.

The flicker compensation circuit according to an embodiment of the present disclosure may program a gate-source voltage (or a driving current) of the n^{th} frame to drive a light emitting element OLED of each subpixel in steps S4 and S5. In the n^{th} frame, when the low-level source voltage EVSS is reduced, a charge time of an internal capacitor Coled of the light emitting element OLED may be shortened, and thus, VRR flicker may decrease.

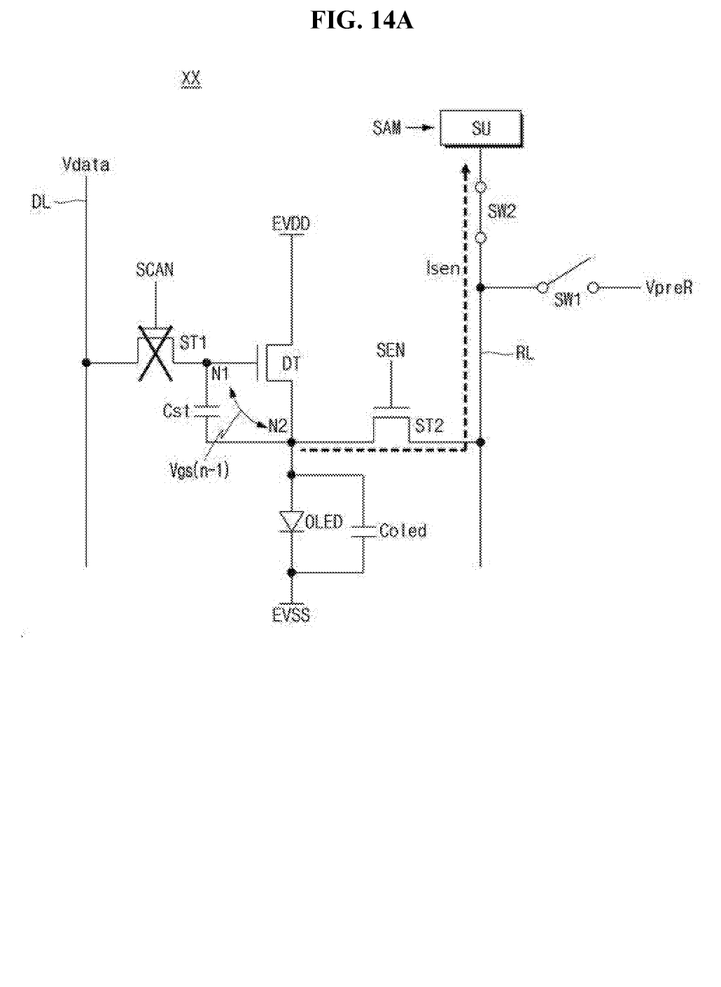

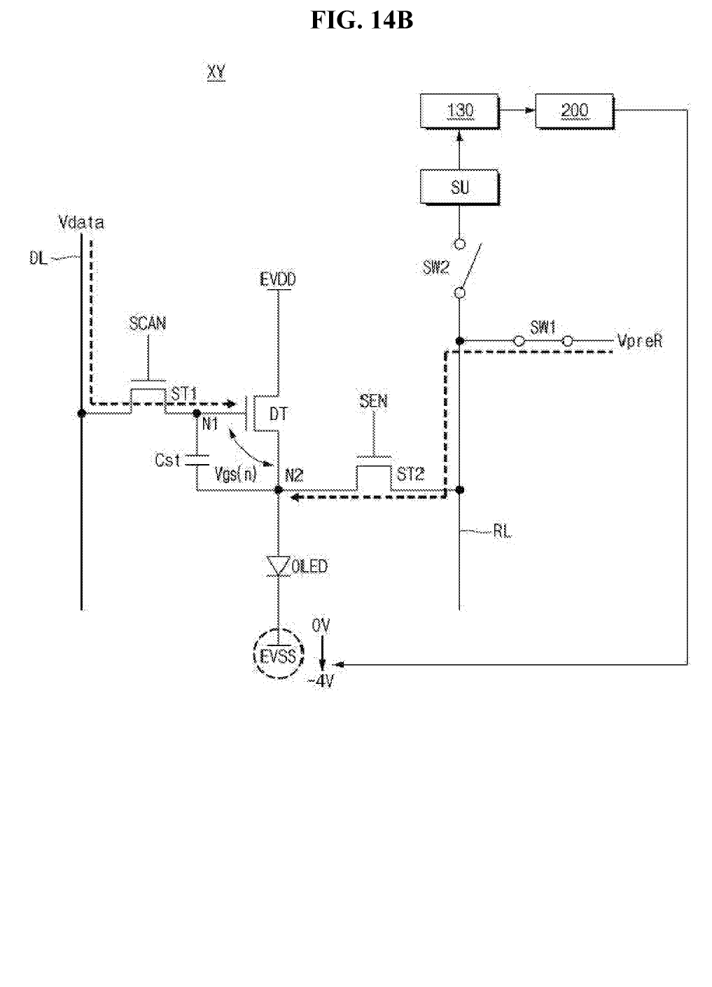

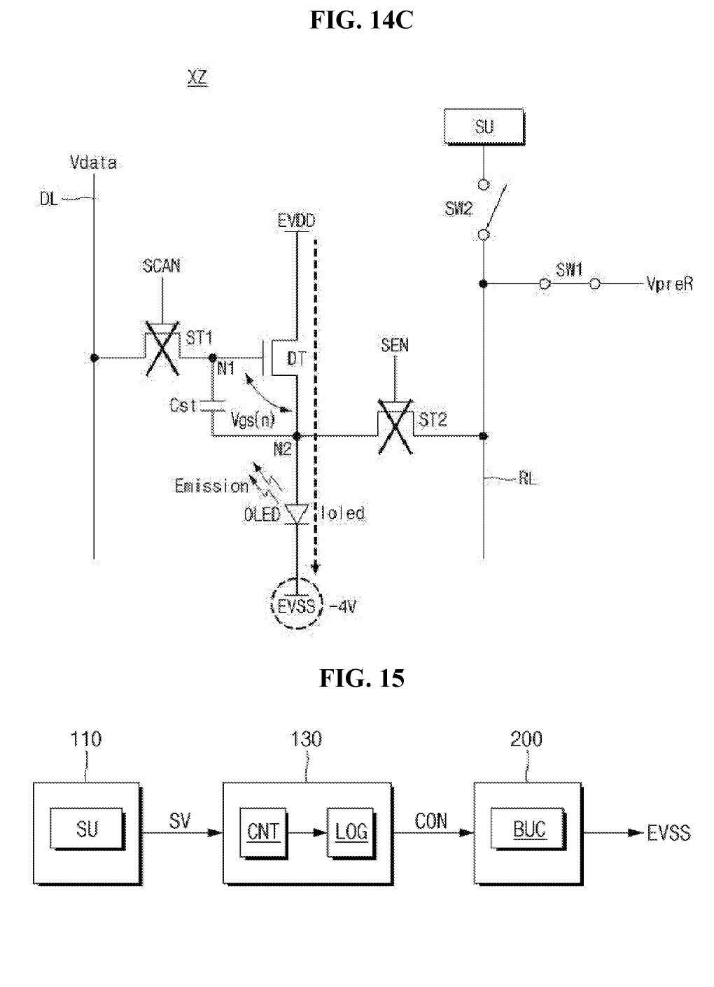

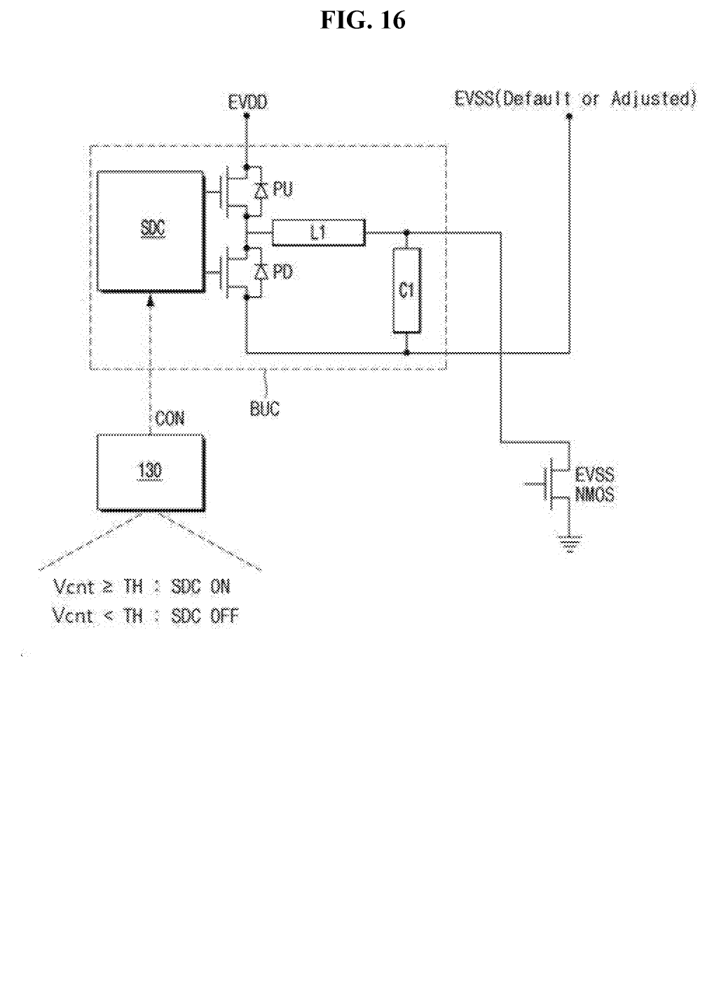

FIG. 13 is a diagram illustrating in detail a driving waveform of a subpixel of an n^{th} frame. FIG. 14A is a diagram illustrating an operation of a subpixel in an XX period of FIG. 13. FIG. 14B is a diagram illustrating an operation of a subpixel in an XY period of FIG. 13. FIG. 14C is a diagram illustrating an operation of a subpixel in an XZ period of FIG. 13.

Referring to FIG. 13, an n^{th} frame may be divided into a current sensing period XX, a data programming period XY, and an OLED emission period XZ, which are sequentially arranged. The current sensing period XX may be set to be far shorter than the data programming period XY, and thus, may prevent a voltage variation of a reference voltage line RL from affecting a data programming operation of each of subpixels disposed in another pixel row.

Referring to FIGS. 13 and 14A, in the current sensing period XX, a driving current Isen of an (n-1)^{th} frame corresponding to a gate-source voltage Vgs(n-1) of the (n-1)^{th} frame may flow through a driving transistor DT. In the current sensing period XX, a first switch transistor ST1 may be turned off by a scan signal SCAN of an off level, and a second switch transistor ST2 may be turned on by a sense signal SEN of an on level. Also, the first switch SW1 may be turned off, and the second switch SW2 may be turned on. As a result, a driving current Isen of the (n-1)^{th} frame flowing through the driving transistor DT may be input to a sensing circuit SU via the second switch transistor ST2, a reference voltage line RL and the second switch SW2.

In the current sensing period XX, the sensing circuit SU may sample the driving current Isen of the (n-1)^{th} frame to output a sensing value, based on a sampling signal SAM. The sensing value may represent a first value in a black subpixel and may represent a second value which is greater than the first value in a non-black subpixel. The second value may increase as a gray level implemented in the non-black subpixel is brightened.

Referring to FIGS. 13 and 14B, in the data programming period XY, the first switch transistor ST1 may be turned on by the scan signal SCAN of an on level, and the second switch transistor ST2 may be turned on by the sense signal SEN of an on level. Also, the first switch SW1 may be turned on, and the second switch SW2 may be turned off. A data voltage Vdata may be charged in a data line DL.

In the data programming period XY, a gate-source voltage Vgs(n) of an n^{th} frame may be programmed on the driving transistor DT. The gate-source voltage Vgs(n) of the n^{th} frame may be “Vdata-VpreR”.

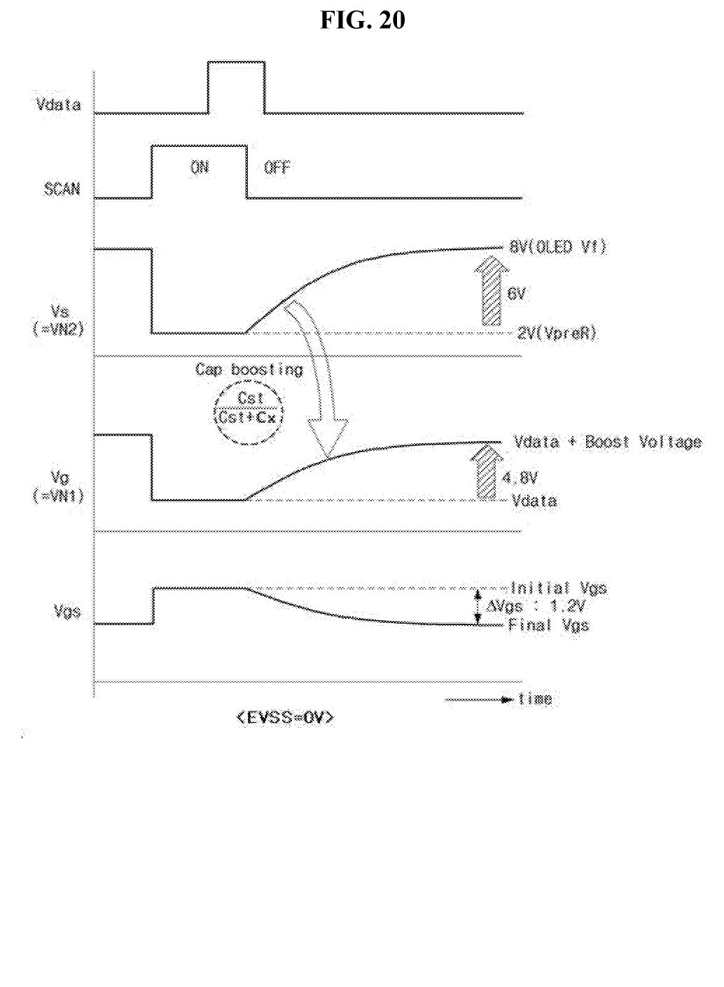

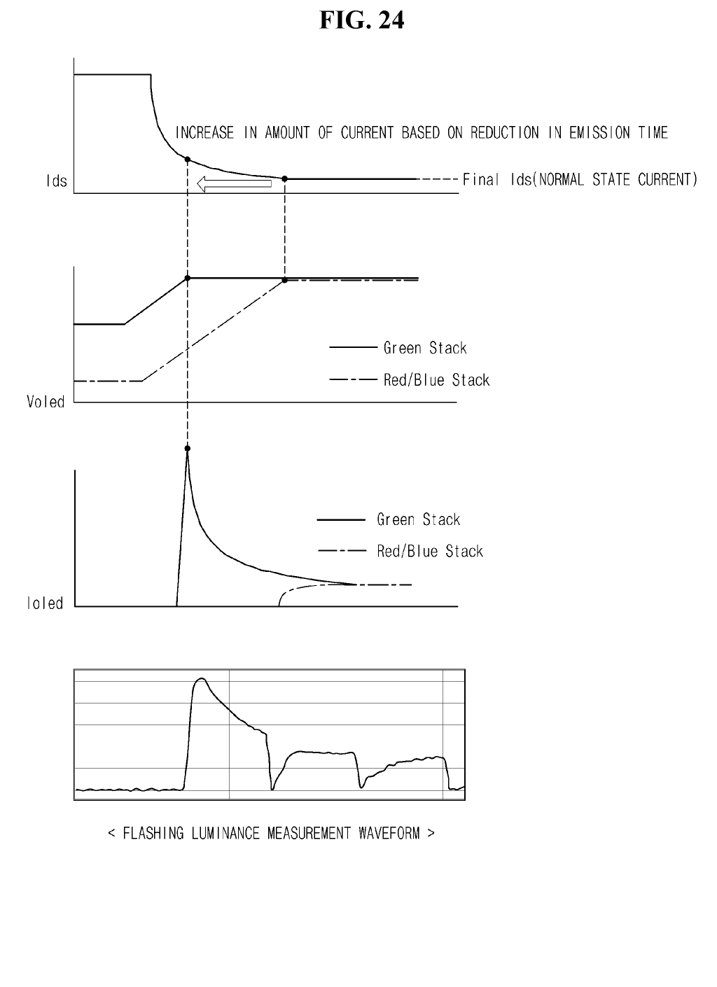

Moreover, in the data programming period XY, a timing controller 130 may count a sensing value of the first value received from the sensing circuit SU, and thus, may count the number of black subpixels included in an (n-1)^{th} frame image. When the number of black subpixels is greater than or equal to a predetermined register value, the timing controller 130 may control a power circuit 200 to reduce a low-level source voltage EVSS to an adjustment voltage level (for example, -4 V) which is lower than a default voltage level (for example, 0 V). The reason that the low-level source voltage EVSS is down-adjusted in a low grayscale image where the number of black subpixels is greater than or equal to the predetermined register value may be for improving VRR flicker and a flashing phenomenon. The principle that VRR flicker is improved will be described below with reference to FIGS. 19 to 22. The principle that a flashing phenomenon is improved will be described below with reference to FIGS. 23 to 25.

Referring to FIGS. 13 and 14C, in the OLED emission period XZ, the first switch transistor ST1 may be turned off by the scan signal SCAN of an off level, and the second switch transistor ST2 may be turned off by the sense signal SEN of an off level. In the OLED emission period XZ, the gate-source voltage Vgs(n) of the n^{th} frame may be held, and a driving current Ioled corresponding to the gate-source voltage Vgs(n) of the n^{th} frame may flow through the driving transistor DT. The light emitting element OLED may emit light with the driving current Ioled. Because the low-level source voltage EVSS is down-adjusted, VRR flicker occurring in a rapid change condition of a frame frequency may be improved, and moreover, an over-emission current level flowing through the light emitting element OLED may be lowered, and flashing may be prevented.

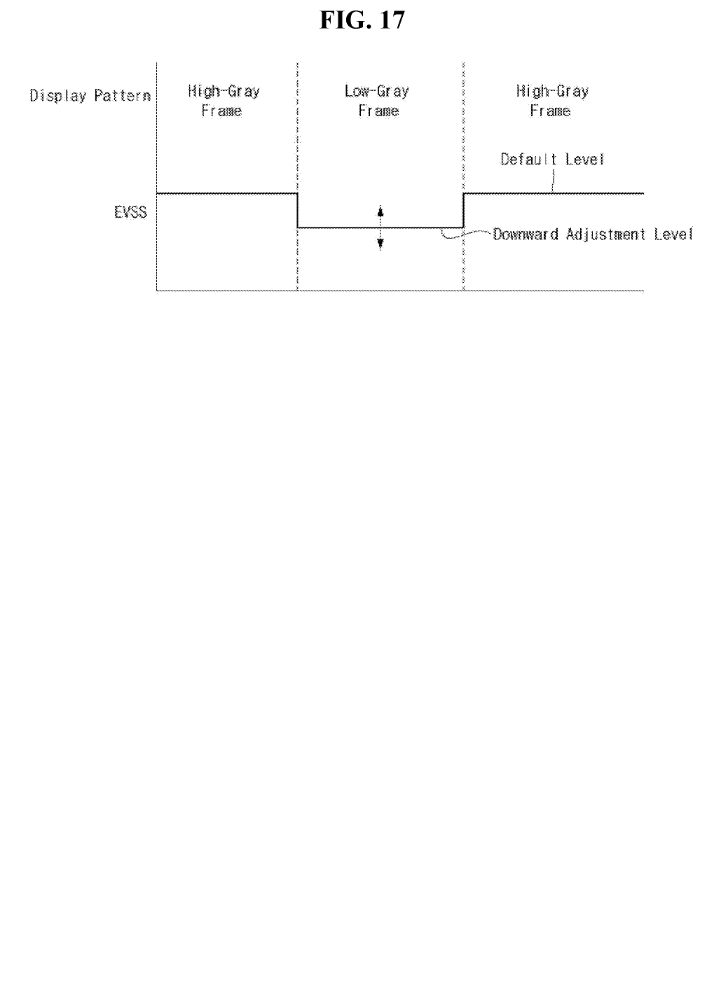

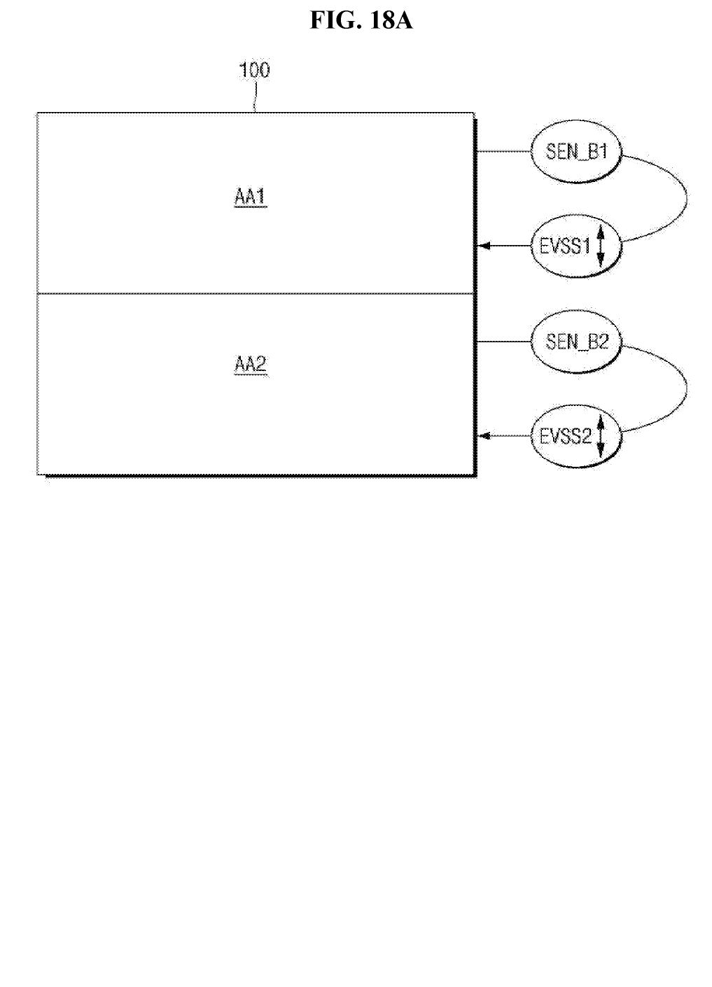

FIG. 15 is a diagram illustrating a connection configuration between a timing controller, a power circuit, and a sensing circuit for adjusting a voltage level of a low-level source voltage according to an embodiment of the present disclosure. FIG. 16 is a diagram illustrating a configuration example of a power circuit adjusting a voltage level of a low-level source voltage, based on the number of black subpixels.

Referring to FIG. 15, a sensing circuit SU may be implemented as a current integrator for sensing a driving current of an (n-1)^{th} frame, but is not limited thereto. The sensing circuit SU may be embedded in a source driver 110 and may sample the driving current of the (n-1)^{th} frame to output a sensing value SV.

Referring to FIG. 15, a timing controller 130 may output a power control signal CON, based on the sensing value SV. A counter CNT of the timing controller 130 may count the number of black subpixels included in the (n-1)^{th} frame with reference to the sensing value SV. When the number of black subpixels is less than a predetermined register setting value, a logic unit LOG of the timing controller 130 may output the power control signal CON as a first value, and when the number of black subpixels is greater than or equal to the predetermined register setting value, the logic unit LOG of the timing controller 130 may output the power control signal CON as a second value which differs from the first value.

Referring to FIG. 15, a power circuit 200 may adjust a voltage level of a low-level source voltage EVSS, based on the power control signal CON.

A buck converting circuit BUC of the power circuit 200 may include a step-down converter SDC where an operation thereof is turned on or off based on the power control signal CON and an output stabilization circuit which is connected to an output of the step-down converter SDC.

When a count value Vcnt of the number of black subpixels is less than a register setting value TH, the timing controller 130 may output the power control signal CON of a first value SDC OFF, and when the count value Vcnt of the number of black subpixels is greater than or equal to the register setting value TH, the timing controller 130 may output the power control signal CON of a second value SDC ON.

The step-down converter SDC may off-operate in response to the power control signal CON of the first value SDC OFF, and thus, the low-level source voltage EVSS may be output at a default voltage level.

The step-down converter SDC may on-operate in response to the power control signal CON of the second value SDC ON, and thus, the low-level source voltage EVSS may be output at an adjustment voltage level which is lower than the default voltage level.

The output stabilization circuit may stabilize an output of the step-down converter SDC. The output stabilization circuit may include a pull-up switch PU, a pull-down switch PD, and an inductor L1 and a capacitor C1 serially connected between a first electrode and a second electrode of the pull-down switch PD. An EVSS NMOS switch which is turned on/off in conjunction with an on/off operation of the step-down converter SDC may be further connected to one side of each of the inductor L1 and the capacitor C1. As shown in FIG. 16, the EVSS NMOS switch is connected to a node between inductor L1 and capacitor C1

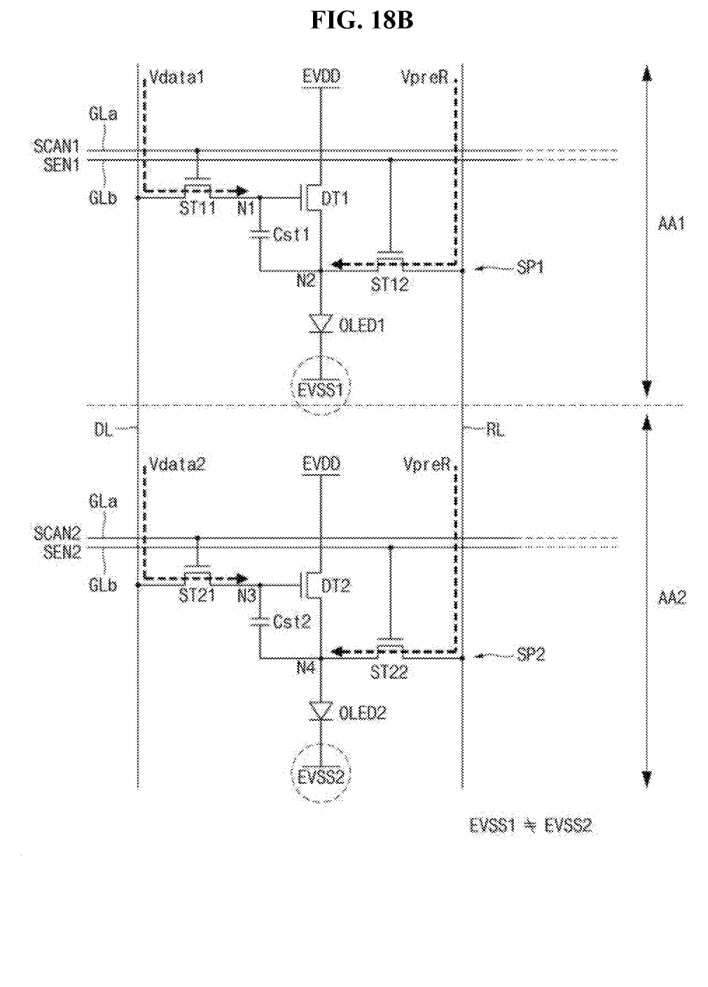

FIG. 17 is a diagram illustrating an example where a low-level source voltage is adjusted to be lower in a low grayscale image frame than a high grayscale image frame.

Referring to FIG. 17, VRR flicker and a flashing phenomenon may not be issued in a high grayscale frame where a high grayscale image is displayed, but may be issued in a low grayscale frame where a low grayscale image is displayed. Accordingly, the display apparatus according to an embodiment of the present disclosure may maintain a low-level source voltage EVSS at a default voltage level in a high grayscale frame and may down-adjust the low-level source voltage EVSS to a voltage level which is lower than the default voltage level, in a low grayscale frame.

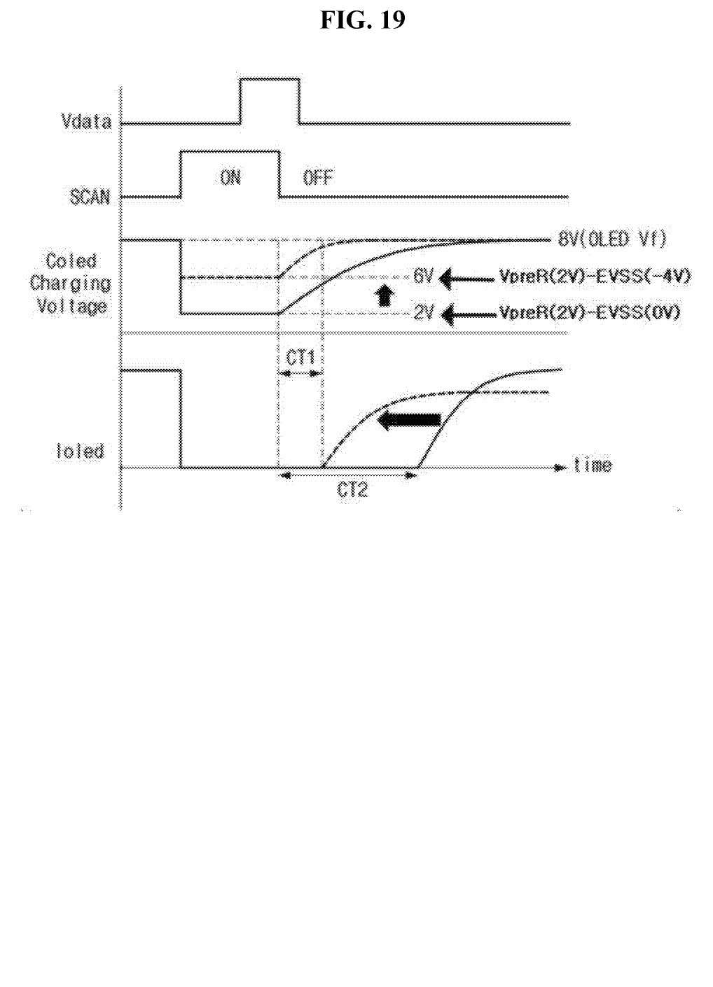

FIGS. 18A and 18B are diagrams illustrating an example where a voltage level of a low-level source voltage is differently adjusted in a first display area and a second display area of a display panel.

Referring to FIGS. 18A and 18B, a voltage level of a low-level source voltage EVSS may be differently adjusted in a first display area AA1 and a second display area AA2 of a display panel 100. The voltage level of the low-level source voltage EVSS may be EVSS1 in the first display area AA1, and the voltage level of the low-level source voltage EVSS may be EVSS2 in the second display area AA2. EVSS1 may be determined based on a first sensing value SEN_B1 corresponding to first subpixels SP1 disposed in the first display area AA1, and EVSS2 may be determined based on a second sensing value SEN_B2 corresponding to second subpixels SP2 disposed in the second display area AA2.

Cathode electrodes of light emitting elements OLED for receiving the low-level source voltage EVSS may be electrically connected to each other in the first display area AA1. Cathode electrodes of light emitting elements OLED for receiving the low-level source voltage EVSS may be electrically connected to each other in the second display area AA2.

However, for individually inputting the low-level source voltage EVSS, cathodes of light emitting elements OLED may be electrically disconnected from each other between the first display area AA1 and the second display area AA2.

In detail, as in FIG. 18B, a first subpixel SP1 disposed in the first display area AA1 and a second subpixel SP2 disposed in the second display area AA2 may share a data line DL and a reference voltage line RL, but may not share a supply line of the low-level source voltage EVSS so as to individually receive the low-level source voltage EVSS.

The first subpixel SP1 may include a first driving transistor DT1, where a gate electrode thereof is connected to a first node N1 and a source electrode thereof is connected to a second node N2, and a first light emitting element OLED1 where an anode electrode thereof is connected to the second node N2, and may be disposed in the first display area AA1. The first subpixel SP1 may further include a switch transistor ST11 which is connected to the data line DL and the first node N1 and is turned on/off based on a first scan signal SCAN1, a switch transistor ST12 which is connected to the reference voltage line RL and the second node N2 and is turned on/off based on a first sense signal SEN1, and a first storage capacitor Cst1 which is connected to the first node N1 and the second node N2.

The second subpixel SP2 may include a second driving transistor DT2, where a gate electrode thereof is connected to a third node N3 and a source electrode thereof is connected to a fourth node N4, and a second light emitting element OLED2 where an anode electrode thereof is connected to the fourth node N4, and may be disposed in the second display area AA2. The second subpixel SP2 may further include a switch transistor ST21 which is connected to the data line DL and the third node N3 and is turned on/off based on a second scan signal SCAN2, a switch transistor ST22 which is connected to the reference voltage line RL and the fourth node N4 and is turned on/off based on a second sense signal SEN2, and a second storage capacitor Cst2 which is connected to the third node N3 and the fourth node N4.

A cathode electrode of the first light emitting element OLED1 included in the first subpixel SP1 may receive the low-level source voltage EVSS of an EVSS1 level. A cathode electrode of the second light emitting element OLED2 included in the second subpixel SP2 may receive the low-level source voltage EVSS of an EVSS2 level which differs from the EVSS1 level.

In a case where an image displayed on the first display area AA1 and an image displayed on the second display area AA2 configures an n^{th} frame image, and the number of black subpixels included in the image displayed on the first display area AA1 is more than the number of black subpixels included in the image displayed on the second display area AA2, the EVSS1 level supplied to the first display area AA1 in common may be adjusted to be lower than the EVSS2 level supplied to the second display area AA2 in common. For example, the EVSS2 level may be 0 V, and the EVSS1 level may be -4 V.

FIG. 19 is a diagram illustrating an example where a Coled charge time is reduced by the down adjustment of a low-level source voltage.

Referring to FIG. 19, when a low-level source voltage EVSS is down-adjusted from 0 V to -4 V in a low grayscale frame, a Coled charge time may be shortened from CT2 to CT1. The Cloled charge time being shortened may denote that a turn-on time of a light emitting element OLED is advanced, and thus, an emission time increases. VRR flicker issued in a low gray level may be associated with a luminance slew rate. When the low-level source voltage EVSS is down-adjusted from 0 V to -4 V, an emission time of the light emitting element OLED in one frame may increase, and thus, a time for reaching target luminance may be shortened in proportion thereto. That is, a luminance slew rate for reaching the target luminance may increase, and thus, VRR flicker issued in a low gray level may be improved.

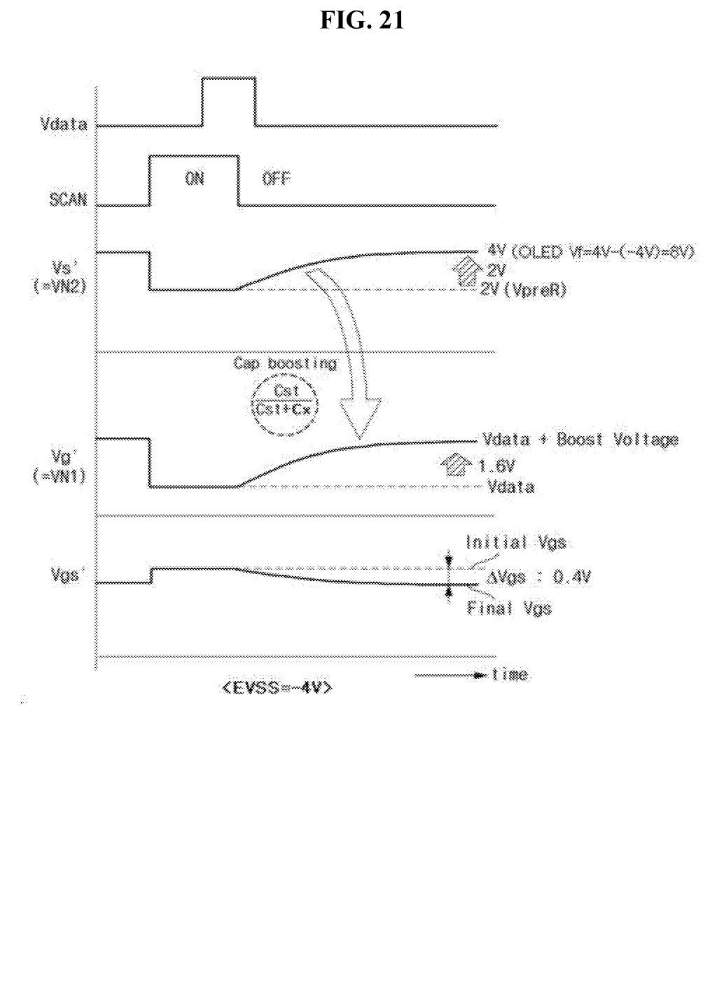

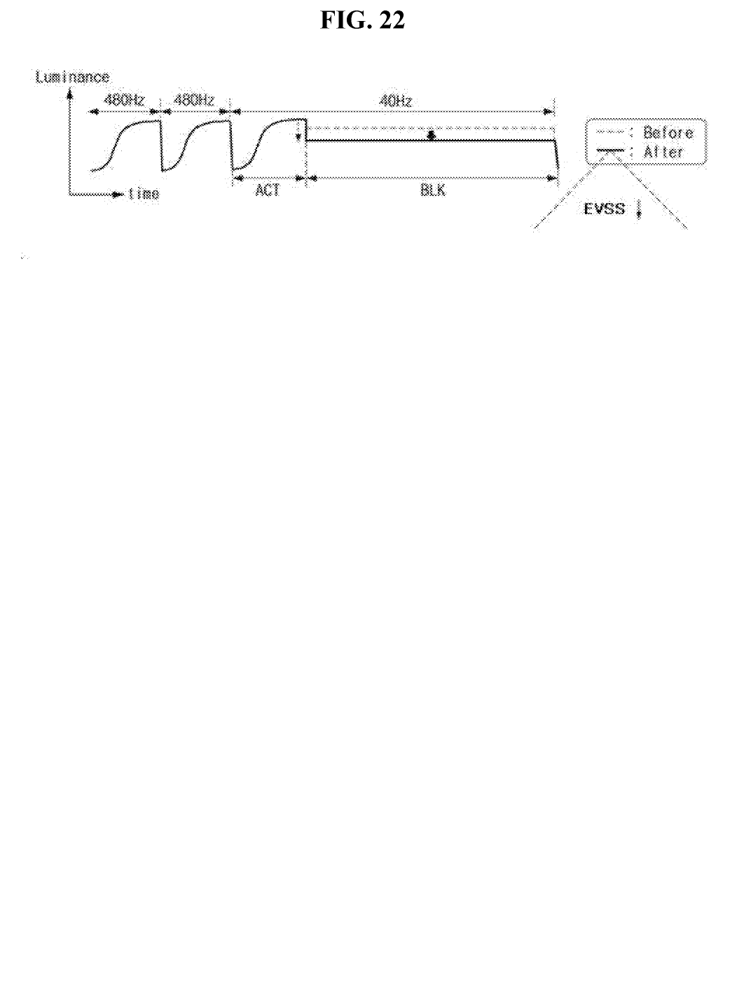

FIG. 20 is a diagram illustrating a Vgs variation of when a low-level source voltage is applied at a default level. FIG. 21 is a diagram illustrating a Vgs variation of when a low-level source voltage is applied at a voltage level which is lower than the default level.

Referring to FIGS. 2 and 20, in a state where the low-level source voltage EVSS is applied to the cathode electrode of the light emitting element OLED as 0 V of a default level, when the driving transistor DT operates as the initialization voltage VpreR is applied to the second node N2 as 2 V of a default level and the data voltage Vdata is applied to the first node N1, a source voltage Vs which is a voltage VN2 of the second node N2 may increase by 6 V up to an OLED turn-on voltage Vf of 8 V from 2 V, based on a current flowing through the driving transistor DT. At this time, a gate voltage Vg which is a voltage VN1 of the first node N1 may also increase from the data voltage Vdata to “Vdata + boosting voltage” through cap-boosting based on the storage capacitor Cst. A cap-boosting rate may be defined as “capacitance Cst/(capacitance Cst + parasitic capacitance Cx)”. When the cap-boosting rate is 80%, a boosting voltage may be 6V*0.8, namely, may be 4.8 V. That is, the gate voltage Vg may increase to “Vdata+4.8V”. As a result, a difference voltage △Vgs between initial Vgs and final Vgs may be 1.2 V. The initial Vgs may be a gate-source voltage of the driving transistor DT based on driving current programming. The final Vgs may be a gate-source voltage of the driving transistor DT at an emission time of the light emitting element OLED. As described above, when △Vgs is high, a drain-source current deviation △Ids of the driving transistor DT may increase. When the drain-source current deviation △Ids of the driving transistor DT increases, a recognition luminance change may increase, and due to this, VRR flicker may be easily recognized in a low gray level.

Referring to FIGS. 2 and 21, when the low-level source voltage EVSS is lowered to -4 V and applied to the cathode electrode of the light emitting element OLED, the OLED turn-on voltage Vf may decrease by 4 V from 8 V, and thus, the source voltage Vs may quickly increase by 2 V from 2 V to 4 V which is the OLED turn-on voltage Vf, based on a current flowing through the driving transistor DT. At this time, the gate voltage Vg may also increase from the data voltage Vdata to “Vdata + boosting voltage” through cap-boosting based on the storage capacitor Cst. When the cap-boosting rate is 80%, a boosting voltage may be 2V*0.8, namely, may be 1.6 V. That is, the gate voltage Vg may increase to “Vdata+1.6V”. As a result, the difference voltage △Vgs between the initial Vgs and the final Vgs may be 0.4 V. As described above, when △Vgs deceases through the down-adjustment of the low-level source voltage EVSS, the drain-source current deviation △Ids of the driving transistor DT may decrease. When the drain-source current deviation △Ids of the driving transistor DT decreases, a recognition luminance change may decrease, and thus, VRR flicker may be prevented in a low gray level.

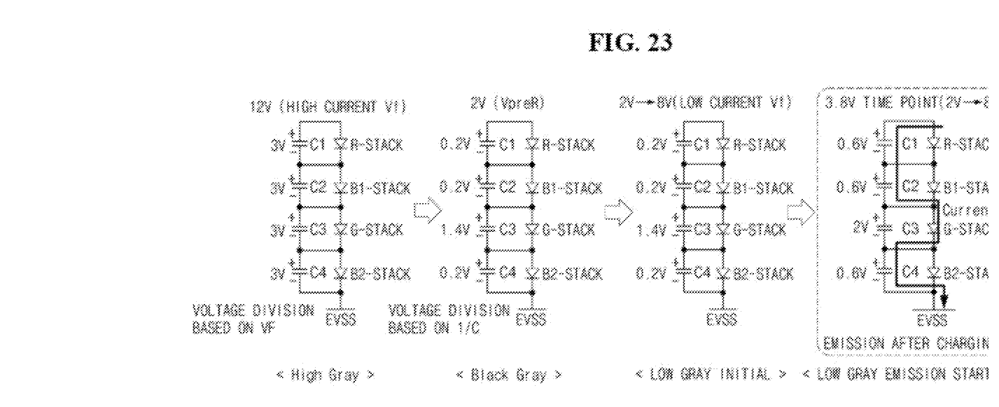

FIG. 22 is a diagram illustrating an example where VRR flicker is reduced when a low-level source voltage is down-adjusted.

Referring to FIG. 22, in a case where a low-level source voltage EVSS is down-adjusted, even when a frame frequency is rapidly changed from 480 Hz to 40 Hz, a peak luminance of a low grayscale area may be reduced, and thus, VRR flicker may be improved.

FIGS. 23 and 24 are diagrams illustrating an example where an abnormal flashing phenomenon occurs due to a capacitance deviation of capacitors configuring an OLED multi-stack.

Referring to FIG. 23, a capacitance of a G stack may be 75% larger than capacitances of a R stack, a B1 stack, and a B2 stack.

When implementing a high gray level, the R stack, the B1 stack, the G stack, and the B2 stack may divide a high current OLED turn-on voltage Vf of 12 V by units of 3 V.

Subsequently, when implementing a black gray level, the R stack, the B1 stack, the G stack, and the B2 stack may divide a voltage, based on 1/capacitance. The B1 stack, the G stack, and the B2 stack may respectively divide an initialization voltage VpreR of 2 V into 0.2 V, 0.2 V, 1.4 V, and 0.2 V.

Subsequently, at an initial time for low gray level implementation, the R stack, the B1 stack, the G stack, and the B2 stack may respectively divide 2 V into 0.2 V, 0.2 V, 1.4 V, and 0.2 V.

Subsequently, at an emission start time for low gray level implementation, the R stack, the B1 stack, the G stack, and the B2 stack may respectively divide 3.8 V into 0.6 V, 0.6 V, 2 V, and 0.6 V. At this time, an emission time of the G stack may be earlier than emission times of the R stack, the B1 stack, and the B2 stack. As the emission time of the G stack is pulled forward, the amount of current may increase, and due to this, abnormal transition emission (i.e., flashing) may occur.

As described above, an abnormal flashing phenomenon may cause a capacitance unbalance of each stack.

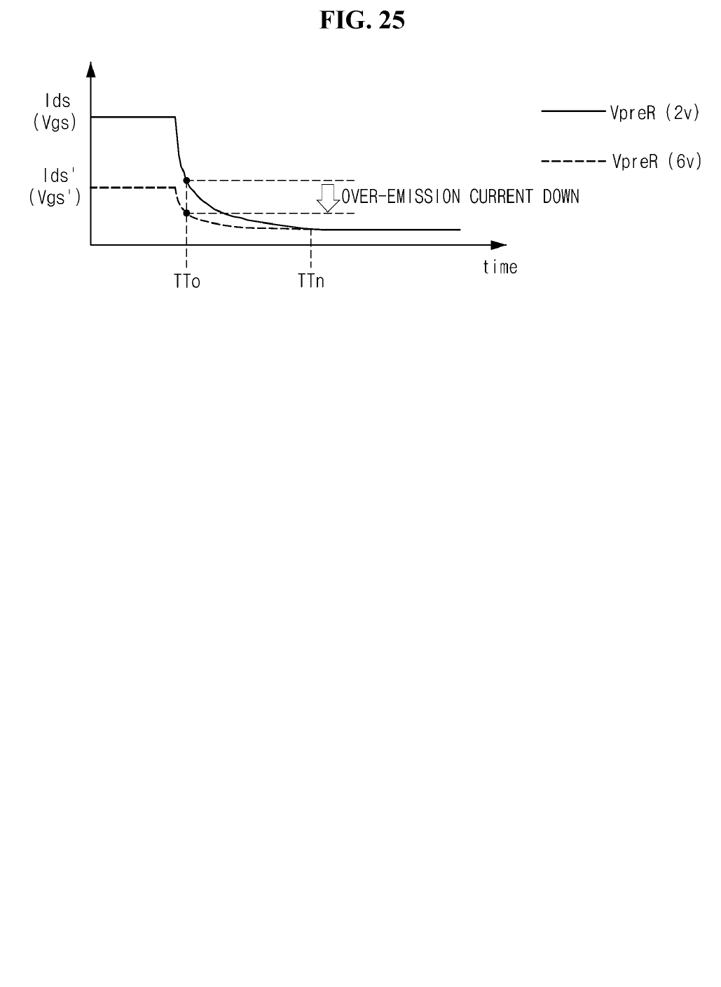

FIG. 25 is a diagram illustrating an example where △Vgs is reduced when a low-level source voltage decreases, and thus, an over-emission current level is lowered, and flashing is prevented.

Referring to FIG. 25, when a low-level source voltage EVSS is down-adjusted from 0 V to -4 V, an over-emission current level at an early emission time TTo which is earlier than a normal emission time TTn may be lowered, and thus, despite early emission, abnormal flashing may be effectively prevented.

The embodiments of the present disclosure may realize the following effects.

The present disclosure may reduce a voltage level of a low-level source voltage in a low grayscale frame. Accordingly, the present disclosure may decrease a low grayscale recognition luminance deviation occurring in a rapid change condition of a frame frequency to improve VRR flicker and abnormal flashing, thereby enhancing display quality.

The effects according to the present disclosure are not limited to the above examples, and other various effects may be included in the specification.

While the present disclosure has been particularly shown and described with reference to example embodiments thereof, it will be understood by those of ordinary skill in the art that various changes in form and details may be made therein without departing from the spirit and scope of the present disclosure as defined by the following claims.

What is claimed is:

1. A display apparatus, comprising:
a display panel including a plurality of subpixels disposed therein, each of the plurality of subpixels including a driving element and a light emitting element connected between a high-level source voltage and a low-level source voltage;
a sensing circuit configured to, during an n^{th} (where n is a natural number) frame, sense a driving current of an (n-1)^{th} frame flowing through the driving element to output a sensing value, before a gate-source voltage of the n^{th} frame on the driving element is programmed;
a timing controller configured to output a power control signal, based on the sensing value; and
a power circuit configured to adjust a voltage level of the low-level source voltage, based on the power control signal.

2. The display apparatus of claim 1, wherein the timing controller comprises a counter configured to count a number of black subpixels included in an (n-1)^{th} frame image with reference to the sensing value, and
wherein when the number of black subpixels is less than a predetermined register setting value, the timing controller outputs the power control signal as a first value, and
wherein when the number of black subpixels is greater than or equal to the predetermined register setting value, the timing controller outputs the power control signal as a second value which differs from the first value.

3. The display apparatus of claim 2, wherein the power circuit outputs the low-level source voltage at a default voltage level, based on the power control signal of the first value, and outputs the low-level source voltage at an adjustment voltage level which is lower than the default voltage level, based on the power control signal of the second value.

4. The display apparatus of claim 1, wherein a frame frequency of the display apparatus when displaying the (n-1)^{th} frame is different from the frame frequency of the display apparatus when displaying the n^{th} frame.

5. The display apparatus of claim 1, wherein the (n-1)^{th} frame comprises an (n-1)^{th} vertical active period during which a gate-source voltage of the (n-1)^{th} frame corresponding to the driving current of the (n-1)^{th} frame is programmed and an (n-1)^{th} vertical blank period during which the gate-source voltage of the (n-1)^{th} frame is held,
wherein the n^{th} frame comprises an n^{th} vertical active period during which the gate-source voltage of the n^{th} frame is programmed and an n^{th} vertical blank period during which the gate-source voltage of the n^{th} frame is held,
wherein the (n-1)^{th} vertical active period is same as the n^{th} vertical active period, and
wherein the n^{th} vertical blank period is longer than the (n-1)^{th} vertical blank period.

6. The display apparatus of claim 1, wherein a time for which the driving current of the (n-1)^{th} frame is sensed is shorter than a time for which the gate-source voltage of the n^{th} frame is programmed.

7. The display apparatus of claim 1, wherein the light emitting element comprises a red color stack, a first blue color stack, a green color stack, and a second blue color stack, which are sequentially stacked.

8. The display apparatus of claim 1, wherein the display panel is divided into a first display area where some of the plurality of subpixels are disposed and a second display area where the other subpixels are disposed, and
wherein a voltage level of the low-level source voltage in the first display area differs from a voltage level of the low-level source voltage in the second display area.

9. The display apparatus of claim 8, wherein the voltage level of the low-level source voltage in the first display area and the voltage level of the low-level source voltage in the second display area are adjusted differently,
wherein the voltage level of the low-level source voltage in the first display area is determined based on the sensing value of the driving current in the (n-1)^{th} frame corresponding to the subpixels in the first display area sensed by the sensing circuit, and
wherein the voltage level of the low-level source voltage in the second display area is determined based on the sensing value of the driving current in the (n-1)^{th} frame corresponding to the subpixels in the second display area sensed by the sensing circuit.

10. The display apparatus of claim 9, wherein, in a (n-1)^{th} frame image, when the number of black subpixels in an image displayed on the first display area is greater than the number of black subpixels in an image displayed on the second display area, the voltage level of the low-level source voltage in the first display area is adjusted to be lower than the voltage level of the low-level source voltage in the second display area.

11. A display apparatus, comprising:
a display panel including a plurality of subpixels disposed therein, each of the plurality of subpixels including a driving element and a light emitting element connected between a high-level source voltage and a low-level source voltage;
a sensing circuit configured to, during an n^{th} (where n is a natural number) frame, sense a driving current of an (n-1)^{th} frame flowing through the driving element before a gate-source voltage of the n^{th} frame on the driving element is programmed; and
a power circuit configured to adjust a voltage level of the low-level source voltage, based on a driving current sensing value of the (n-1)^{th} frame,
wherein, when a number of black subpixels of an (n-1)^{th} frame image corresponding to the driving current of the (n-1)^{th} frame is a first value within a predetermined range, the power circuit outputs the low-level source voltage at a default voltage level in the n^{th} frame, and
when the number of black subpixels of the (n-1)^{th} frame image corresponding to the driving current of the (n-1)^{th} frame is a second value outside the predetermined range, the power circuit outputs the low-level source voltage at an adjustment voltage level which is lower than the default voltage level, in the n^{th} frame.

12. The display apparatus of claim 11, wherein the second value outside the predetermined range is a value higher than the predetermined range.

13. The display apparatus of claim 11, wherein a frame frequency of the display apparatus when displaying the (n-1)^{th} frame is different from the frame frequency of the display apparatus when displaying the nth frame.

14. The display apparatus of claim 11, wherein the light emitting element comprises a red color stack, a first blue color stack, a green color stack, and a second blue color stack, which are sequentially stacked.

15. The display apparatus of claim 11, wherein the display panel is divided into a first display area where some of the plurality of subpixels are disposed and a second display area where the other subpixels of the plurality of subpixels are disposed, and
wherein a voltage level of the low-level source voltage in the first display area differs from a voltage level of the low-level source voltage in the second display area.

16. The display apparatus of claim 15, wherein the voltage level of the low-level source voltage in the first display area and the voltage level of the low-level source voltage in the second display area are adjusted differently,
wherein the voltage level of the low-level source voltage in the first display area is determined based on the sensing value of the driving current in the (n-1)^{th} frame corresponding to the subpixels in the first display area sensed by the sensing circuit, and
wherein the voltage level of the low-level source voltage in the second display area is determined based on the sensing value of the driving current in the (n-1)th frame corresponding to the subpixels in the second display area sensed by the sensing circuit.

17. The display apparatus of claim 16, wherein, in a (n-1)^{th} frame image, when the number of black subpixels in an image displayed on the first display area is greater than the number of black subpixels in an image displayed on the second display area, the voltage level of the low-level source voltage in the first display area is adjusted to be lower than the voltage level of the low-level source voltage in the second display area.

18. A driving method of a display apparatus including a display panel including a plurality of subpixels disposed therein, each of the plurality of subpixels including a driving element and a light emitting element connected between a high-level source voltage and a low-level source voltage, the driving method comprising:
during an n^{th} (where n is a natural number) frame, sensing a driving current of an (n-1)^{th} frame flowing through the driving element before a gate-source voltage of the n^{th} frame on the driving element is programmed; and
adjusting a voltage level of the low-level source voltage, based on a driving current sensing value of the (n-1)^{th} frame,
wherein the adjusting of the voltage level of the low-level source voltage comprises:
when a number of black subpixels of an (n-1)^{th} frame image corresponding to the driving current of the (n-1)^{th} frame is a first value within a predetermined range, outputting the low-level source voltage at a default voltage level in the n^{th} frame; and
when the number of black subpixels of the (n-1)^{th} frame image corresponding to the driving current of the (n-1)^{th} frame is a second value outside the predetermined range, outputting the low-level source voltage at an adjustment voltage level which is lower than the default voltage level, in the n^{th} frame.

19. The driving method of claim 18, wherein the second value outside the predetermined range is a value higher than the predetermined range.

20. The driving method of claim 18, wherein a frame frequency of the display apparatus when displaying the (n-1)^{th} frame is different from the frame frequency of the display apparatus when displaying the n^{th} frame.
